(19) United States
(12) Patent Application Publication
(10) Pub. No.: US 2024/0300990 A1
(43) Pub. Date: Sep. 12, 2024

(54) ORGANIC COMPOUND AND ORGANIC LIGHT-EMITTING DEVICE INCLUDING THE SAME

(71) Applicant: Material Science Co.,Ltd., Seoul (KR)

(72) Inventors: Hee-Jun PARK, Seoul (KR); Seung-Hyun KIM, Seoul (KR)

(21) Appl. No.: 18/589,872

(22) Filed: Feb. 28, 2024

(30) Foreign Application Priority Data
Mar. 2, 2023 (KR) 10-2023-0027515
Feb. 27, 2024 (KR) 10-2024-0028303

(51) Int. Cl. C07F 17/02; H10K 50/844

(52) U.S. Cl. CPC C07F 17/02; H10K 50/844

(57) ABSTRACT

A compound represented by the Chemical Formula 1 has a high-density and thus constitutes a dense film structure. Moreover, the compound represented by the Chemical Formula 1 binds to oxygen or moisture, thereby suppressing penetration of oxygen or moisture into the organic light-emitting device. In addition, the organic light-emitting device including a novel compound represented by a Chemical Formula 1 has a low operation voltage and has excellent luminous efficiency, excellent external quantum efficiency (EQE), a long lifetime, and excellent stability.

### CROSS-REFERENCE TO RELATED APPLICATION

This application claims priority from Korean Patent Application No. 10-2023-0027515 filed on Mar. 2, 2023 and Korean Patent Application No. 10-2024-0028303 filed on Feb. 27, 2024 in the Korean Intellectual Property Office, and all the benefits accruing therefrom under 35 U.S.C. 119, the contents of which in its entirety are herein incorporated by reference.

### BACKGROUND

### Field

The present disclosure relates to an organic compound and an organic light-emitting device including the same.

### Description of Related Art

An organic light-emitting device (OLED) has a simpler structure compared to other flat panel display devices such as a liquid crystal display (LCD), a plasma display panel (PDP), and a field emission display (FED), and has various advantages in terms of a manufacturing process, and has excellent high luminance and wide viewing angle, fast response speed, and low operation voltage, and thus is being actively developed and commercialized as a flat display such as a wall-mounted TV, a backlight for a display, lighting, and billboards.

The organic light-emitting device includes two electrodes, and an organic material layer therebetween. Electrons and holes from two electrodes are injected into a light-emitting layer in which excitons are generated via recombination of electrons and holes. When the generated excitons change from an excited state to a ground state, the light is generated.

The organic light-emitting device may include at least one light-emitting layer. In general, the organic light-emitting device having a plurality of light-emitting layers includes light-emitting layers that emit light beams with different peak wavelengths. Thus, a specific color may be rendered via a combination of the light beams with the different peak wavelengths.

The organic light-emitting device may be classified into a top emission type light-emitting device and a bottom emission type light-emitting device. The top emission type light-emitting device emits light generated in the light-emitting layer toward a translucent anode using a reflective cathode. On the other hand, in the bottom emission type light-emitting device, light generated in the light-emitting layer is reflected from a reflective anode to be directed toward a transparent cathode, that is, toward a driving thin film transistor.

Conventionally, a capping layer acts as a protective film formed to protect an easily corroded reflective electrode of the organic light-emitting device and is made of an organic compound. However, oxygen or moisture may invade into the organic compound thin film. Thus, when the capping layer is stored or used for a long period of time, efficiency and aa lifetime thereof are reduced. To solve this problem, efforts have been made to develop a compound for an electrode protective film to prevent oxygen or moisture penetration thereto.

### PRIOR ART LITERATURE

### Patent Document

Prior Patent Document 1: CN 106317129 A
Prior Patent Document 2: CN 110016060 A
Prior Patent Document 3: KR 10-2022-0087590

### SUMMARY

A purpose of the present disclosure is to provide a novel organic compound and an organic light-emitting device including the same.

Purposes of the present disclosure are not limited to the above-mentioned purpose. Other purposes and advantages of the present disclosure that are not mentioned may be understood based on following descriptions, and may be more clearly understood based on embodiments of the present disclosure. Further, it will be easily understood that the purposes and advantages of the present disclosure may be realized using means shown in the claims and combinations thereof.

According to one aspect of the present disclosure, a compound represented by a following Chemical Formula 1 may be provided:

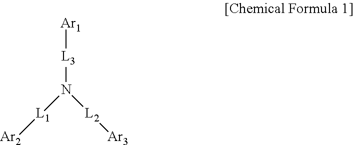

where a definition of the following Chemical Formula 1 is the same as that stated in the present disclosure and claims.

According to another aspect of the present disclosure, there may be provided an organic light-emitting device including a first electrode; a second electrode facing the first electrode; and one or more organic layers between the first electrode and the second electrode, wherein one or more capping layers are disposed on a surface of the first electrode or the second electrode, wherein at least one of the capping layers includes the organic compound as described above.

The organic light-emitting device including the novel compound represented by the Chemical Formula 1 in accordance with the present disclosure has a low operation voltage and has excellent luminous efficiency, excellent external quantum efficiency (EQE), a long lifetime, and excellent stability.

Moreover, the compound represented by the Chemical Formula 1 in accordance with the present disclosure has high-density characteristics and constitutes a dense film structure.

Moreover, the compound represented by the Chemical Formula 1 in accordance with the present disclosure binds to oxygen or moisture due to a binding nature of an organometallic compound, thereby suppressing penetration of oxygen or moisture into the organic light-emitting device.

Moreover, the compound represented by the Chemical Formula 1 in accordance with the present disclosure may be used as the capping layer of the organic light-emitting device including the novel compound.

Effects of the present disclosure are not limited to the effects mentioned above, and other effects not mentioned will be clearly understood by those skilled in the art from the descriptions below.

The purposes, solutions, and effects of the disclosure as described above does not specify essential features of claims. Thus, the scope of claims is not limited by the purposes, solutions, and effects of the disclosure as described above.

### DETAILED DESCRIPTIONS

The above-mentioned purposes, features, and advantages are described in detail below, and accordingly, those skilled in the art in the technical field to which the present disclosure belongs will be able to easily implement the technical ideas of the present disclosure.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

In descriptions of temporal relationships, for example, temporal precedent relationships between two events such as “after”, “subsequent to”, “before”, etc., another event may occur therebetween unless “directly after”, “directly subsequent” or “directly before” is not indicated.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “halogen group” includes fluorine, chlorine, bromine and iodine.

As used herein, the term “alkyl group” refers to both straight-chain alkyl radicals and branched-chain alkyl radicals. Unless otherwise specified, an alkyl group contains 1 to 10 carbon atoms. In this case, the alkyl group may include methyl, ethyl, propyl, isopropyl, butyl, secondary butyl, isobutyl, ter-butyl, pentyl, isoamyl, hexyl, etc., but is not limited thereto. Additionally, the alkyl group may be optionally substituted.

As used herein, the term “cycloalkyl group” refers to a cyclic alkyl radical. Unless otherwise specified, a cycloalkyl group contains 3 to 10 carbon atoms. In this case, the cycloalkyl group may include cyclopropyl, cyclobutyl, cyclopentyl, cyclohexyl, norbornyl, adamantyl, etc., but is not limited thereto. Additionally, the cycloalkyl group may be optionally substituted.

As used herein, the term “alkenyl group” refers to both straight-chain alkenyl radicals and branched-chain alkenyl radicals having one or more carbon-carbon double bonds. Unless otherwise specified, an alkenyl group contains 2 to 10 carbon atoms. In this case, the alkenyl group may include vinyl, allyl, isopropenyl, 2-butenyl, etc., but is not limited thereto. Additionally, the alkenyl group may be optionally substituted.

As used herein, the term “cycloalkenyl group” refers to a cyclic alkenyl radical. Unless otherwise specified, a cycloalkenyl group contains 3 to 10 carbon atoms. Additionally, the cycloalkenyl group may be optionally substituted.

As used herein, the term “alkynyl group” refers to both straight-chain and branched-chain alkynyl radicals having one or more carbon-carbon triple bonds. Unless otherwise specified, an alkynyl group contains 2 to 30 carbon atoms. In this case, an alkynyl group may include, but is not limited to, ethynyl, 2-propynyl, etc. Additionally, the alkynyl group may be optionally substituted.

As used herein, the term “cycloalkynyl group” refers to a cyclic alkynyl radical. Unless otherwise specified, a cycloalkynyl group contains 3 to 20 carbon atoms. Additionally, cycloalkynyl groups may be optionally substituted.

The terms “aralkyl group” and “arylalkyl group” as used herein are used interchangeably with each other and refer to an alkyl group having an aromatic group as a substituent. Additionally, the aralkyl group (arylalkyl group) may be optionally substituted.

The terms “aryl group” and “aromatic group” as used herein are used as having the same meaning, and the aryl group includes both a monocyclic group and a polycyclic group. The polycyclic group may include a “fused ring” in which two or more rings are fused with each other such that two carbons are common to two adjacent rings. Moreover, in the polycyclic group, two or more rings may be simply attached or fused to each other. Unless otherwise specified, the aryl group contains 6 to 30 carbon atoms. In this case, the aryl group may include phenyl, naphthyl, anthracenyl, phenanthryl, fluorenyl, dimethylfluorenyl, diphenylfluorenyl, spirofluorenyl, etc. but is not limited thereto. Additionally, the aryl group may be optionally substituted.

The terms “heteroaryl group” and “heteroaromatic group” as used herein are used as having the same meaning, and the heteroaryl group includes both a monocyclic group and a polycyclic group. The polycyclic group may include a “fused ring” in which two or more rings are fused with each other such that two carbons or heteroatoms are common to two adjacent rings. Moreover, in the polycyclic group, two or more rings may be simply attached or fused to each other. Unless otherwise specified, the heteroaryl group contains 1 to 30 carbon atoms. When the heteroaryl group has 1 or 2 carbon atoms, the heteroaryl group includes an additional hetero atom to form a ring. In addition, the heteroaryl group contains 1 to 30 carbon atoms. In this regard, one or more carbons of a ring are replaced with heteroatoms such as oxygen (O), nitrogen (N), sulfur (S), or selenium (Se). In this case, the heteroaryl group may include a 6-membered monocyclic ring such as pyridyl, pyrazinyl, pyrimidinyl, pyridazinyl, and triazinyl, a polycyclic ring such as phenoxathienyl, indolizinyl, indolyl, purinyl, quinolyl, isoquinolyl, benzooxyzolyl, benzothiazolyl, dibenzooxyzolyl, dibenzothiazolyl, benzoimidazolyl, benzofuranyl, dibenzofuranyl, benzothiophenyl, dibenzothiophenyl, phenylcarbezolyl, 9-phenylcarbazolyl, and carbazolyl, and 2-furanyl, N-imidazolyl, 2-isoxazolyl, 2-pyridinyl, 2-pyrimidinyl etc. but is not limited thereto. Additionally, the heteroaryl group may be optionally substituted.

The term “heterocyclic group” as used herein means that at least one of the carbon atoms constituting an aryl group, a cycloalkyl group, a cycloalkenyl group, a cycloalkynyl group, an arylalkyl group, an arylamino group, etc. is substituted with a heteroatom such as oxygen (O), nitrogen (N), sulfur (S), etc. Referring to the above definition, the heterocyclic group may include a heteroaryl group, a heterocycloalkyl group, a heterocycloalkenyl group, a heterocycloalkynyl group, a heteroarylalkyl group, a heteroarylamino group, etc. Additionally, the heterocyclic group may be optionally substituted.

Unless otherwise specified, the term “carbon ring” as used herein may be used as including all of a “cycloalkyl group,” “cycloalkenyl group,” “cycloalkynyl group” as an alicyclic group and “aryl group (aromatic group”) as an aromatic ring group.

Each of the terms “heteroalkyl group”, “heteroalkenyl group”, “heteroalkynyl group”, and “heteroarylalkyl group” as used herein means that one or more of the carbon atoms constituting the group is substituted with a heteroatom such as oxygen (O), nitrogen (N), sulfur (S). Additionally, each of the heteroalkyl group, heteroalkenyl group, heteroalkynyl group, and heteroarylalkyl group may be optionally substituted.

As used herein, the term “alkylamino group,” “aralkylamino group,” “arylamino group,” or “heteroarylamino group” refers to an alkyl group, an aralkyl group, an aryl group, or a heteroaryl group as a heterocyclic group into which an amine group is substituted. In this regard, the amine group may include all of primary, secondary, and tertiary amines. Further, the alkylamino group, the aralkylamino group, the arylamino group, and the heteroarylamino group may be optionally substituted.

As used herein, the term “alkylsilyl group”, “arylsilyl group”, “alkoxy group”, “aryloxy group”, “alkylthio group”, or “arylthio group” refers to each of an alkyl group and an aryl group into which each of a silyl group, an oxy group, and a thio group is substituted. Additionally, the alkylsilyl group, the arylsilyl group, the alkoxy group, the aryloxy group, the alkylthio group, and the arylthio group may be optionally substituted.

The terms “arylene group”, “arylalkylene group”, “heteroarylene group”, or “heteroarylalkylene group” as used herein means a group having two-substitutions in which the aryl group, arylalkyl group, heteroaryl group, or heteroarylalkyl group further includes one substitution. Additionally, the arylene group, arylalkylene group, heteroarylene group, and heteroarylalkylene group may be optionally substituted.

As used herein, the term “substituted” means that a substituent other than hydrogen (H) binds to corresponding carbon. When there are a plurality of substituents, the substituents may be the same as or different from each other.

Unless otherwise specified, a position at which the substitution occurs is not particularly limited as long as a hydrogen atom can be substituted with a substituent at the position. When two or more substituents, that is, the plurality of substituents are present, the substituents may be identical to or different from each other.

Subjects and substituents as defined in the present disclosure may be the same as or different from each other unless otherwise specified.

Hereinafter, an organic compound and an organic light-emitting device including the same according to the present disclosure will be described in detail.

The organic compound in accordance with the present disclosure may be represented by a following Chemical Formula 1:

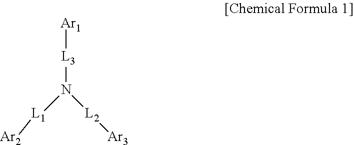

wherein L₁, L₂ and L₃ are identical with or different from each other, and each of L₁, L₂ and L₃ independently represents one selected from a group consisting of a single bond, a substituted or unsubstituted arylene group having 6 to 30 carbon atoms, a substituted or unsubstituted heteroarylene group having 1 to 30 carbon atoms, a substituted or unsubstituted alkylene group having 1 to 10 carbon atoms, a substituted or unsubstituted cycloalkylene group having 3 to 10 carbon atoms, a substituted or unsubstituted alkenylene group having 2 to 10 carbon atoms, a substituted or unsubstituted cycloalkenylene group having 3 to 10 carbon atoms, a substituted or unsubstituted heteroalkylene group having 1 to 10 carbon atoms, a substituted or unsubstituted heterocycloalkylene group having 2 to 10 carbon atoms, a substituted or unsubstituted heteroalkenylene group having 2 to 10 carbon atoms, and a substituted or unsubstituted heterocycloalkenylene group having 2 to 10 carbon atoms,

wherein Ar₁, Ar₂ and Ar₃ are identical with or different from each other, and each of Ar₁, Ar₂ and Ar₃ independently represents one selected from a group consisting of hydrogen, a substituted or unsubstituted aryl group having 6 to 30 carbon atoms, a substituted or unsubstituted heteroaryl group having 1 to 30 carbon atoms, a substituted or unsubstituted alkyl group having 1 to 20 carbon atoms, a substituted or unsubstituted cycloalkyl group having 3 to 20 carbon atoms, a substituted or unsubstituted heteroalkyl group having 1 to 20 carbon atoms, a substituted or unsubstituted heterocycloalkyl group having 2 to 20 carbon atoms, a substituted or unsubstituted aralkyl group having 6 to 30 carbon atoms, a substituted or unsubstituted alkenyl group having 2 to 20 carbon atoms, a substituted or unsubstituted cycloalkenyl group having 3 to 20 carbon atoms, a substituted or unsubstituted heteroalkenyl group having 2 to 20 carbon atoms, and an organometallic compound group represented by a following Chemical Formula 2,

wherein at least one of Ar₁, Ar₂ and Ar₃ is selected as an organometallic compound group represented by the following Chemical Formula 2:

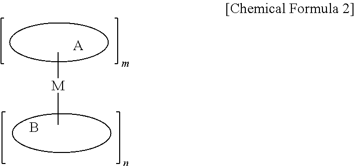

wherein the A ring and the B ring are identical with or different from each other, and each of the A ring and the B ring independently has a monocyclic or polycyclic ring structure including a 5-membered and/or 6-membered carbocyclic or heterocyclic ring,

wherein each of m and n is an integer from 1 to 8,

wherein M independently represents one selected from a group consisting of platinum (Pt), palladium (Pd), copper (Cu), iron (Fe), silver (Ag), gold (Au), rhodium (Rh), ruthenium (Ru), osmium (Os), titanium (Ti), zirconium (Zr), hafnium (Hf), europium (Eu), terbium (Tb), and thulium (Tm),

wherein when a substituent is present in each of L₁, L₂, L₃, Ar₁, Ar₂ and Ar₃, each of the substituents independently represents at least one selected from a group consisting of deuterium, a cyano group, a nitro group, a halogen group, a hydroxy group, an alkyl group having 1 to 30 carbon atoms, an alkenyl group having 2 to 30 carbon atoms, an alkynyl group having 2 to 24 carbon atoms, a heteroalkyl group having 2 to 30 carbon atoms, an aralkyl group having 6 to 30 carbon atoms, a cycloalkyl group having 3 to 20 carbon atoms, a heterocycloalkyl group having 3 to 20 carbon atoms, an aryl group having 6 to 30 carbon atoms, a heteroaryl group having 2 to 30 carbon atoms, a heteroarylalkyl group having 3 to 30 carbon atoms, an alkoxy group having 1 to 30 carbon atoms, an alkylsilyl group having 1 to 30 carbon atoms, an arylsilyl group having 6 to 30 carbon atoms, and an aryloxy group having 6 to 30 carbon atoms, wherein when a plurality of substituents is present in each of L₁, L₂, L₃, Ar₁, Ar₂ and Ar₃, the plurality of substituents are identical with or different from each other.

Further, in an embodiment of the organometallic compound represented by the Chemical Formula 2 of the present disclosure, the organometallic compound is a metallocene represented by a following Chemical Formula 3, wherein in the following Chemical Formula 3, M is the same as defined in the Chemical Formula 1:

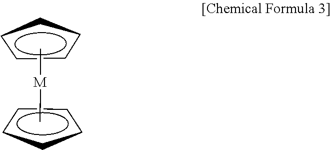

Moreover, in one embodiment of the organometallic compound represented by the Chemical Formula of the present disclosure, the organometallic compound is a ferrocene represented by a following Chemical Formula 4.

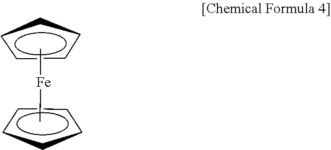

According to one embodiment of the present disclosure, m and/or n may be 1.

According to one embodiment of the present disclosure, each of the A ring and the B ring may be a cyclopentadienyl group.

According to one embodiment of the present disclosure, M may be iron (Fe).

According to one embodiment of the present disclosure, each of at least two of Ar₁, Ar₂, and Ar₃ may be independently selected as the organometallic compound group represented by the Chemical Formula 2, for example, each of two or three of Ar₁, Ar₂, and Ar₃ may be independently selected as the organometallic compound group represented by the Chemical Formula 2.

According to one embodiment of the present disclosure, in the organometallic compound of each of the Chemical Formula 2, the Chemical Formula 3, and the Chemical Formula 4, the A ring or the B ring binds to at least one of L₁, L₂, and L₃ to constitute one moiety of the Chemical Formula 1.

According to one embodiment of the present disclosure, L₁, L₂ and L₃ may be identical with or different from each other, and each of L₁, L₂ and L₃ may independently represent one selected from a group consisting of a single bond, a substituted or unsubstituted arylene group having 6 to 30 carbon atoms, a substituted or unsubstituted heteroarylene group having 5 to 30 carbon atoms, a substituted or unsubstituted alkylene group having 1 to 10 carbon atoms, a substituted or unsubstituted cycloalkylene group having 3 to 10 carbon atoms, a substituted or unsubstituted alkenylene group having 2 to 10 carbon atoms, a substituted or unsubstituted cycloalkenylene group having 3 to 10 carbon atoms, a substituted or unsubstituted heteroalkylene group having 1 to 10 carbon atoms, a substituted or unsubstituted heterocycloalkylene group having 2 to 10 carbon atoms, a substituted or unsubstituted heteroalkenylene group having 2 to 10 carbon atoms, and a substituted or unsubstituted heterocycloalkenylene groups having 2 to 10 carbon atoms.

According to one embodiment of the present disclosure, Ar₁, Ar₂ and Ar₃ may be identical with or different from each other, and each of Ar₁, Ar₂ and Ar₃ may independently represent one selected from a group consisting of hydrogen, a substituted or unsubstituted aryl group having 6 to 30 carbon atoms, a substituted or unsubstituted heteroaryl group having 5 to 30 carbon atoms, a substituted or unsubstituted alkyl group having 1 to 20 carbon atoms, a substituted or unsubstituted cycloalkyl group having 3 to 20 carbon atoms, a substituted or unsubstituted heteroalkyl group having 1 to 20 carbon atoms, a substituted or unsubstituted heterocycloalkyl group having 2 to 20 carbon atoms, a substituted or unsubstituted aralkyl group having 6 to 30 carbon atoms, a substituted or unsubstituted alkenyl group having 2 to 20 carbon atoms, a substituted or unsubstituted cycloalkenyl group having 3 to 20 carbon atoms, a substituted or unsubstituted heteroalkenyl group having 2 to 20 carbon atoms, and the organometallic compound.

According to one embodiment of the present disclosure, L₁, L₂ and L₃ may be identical with or different from each other, and each of L₁, L₂ and L₃ may independently represent one selected from a group consisting of a single bond, a substituted or unsubstituted arylene group having 6 to 30 carbon atoms, and a substituted or unsubstituted heteroarylene group having 5 to 30 carbon atoms.

According to one embodiment of the present disclosure, Ar₁, Ar₂ and Ar₃ may be identical with or different from each other, and each of Ar₁, Ar₂ and Ar₃ may independently represent one selected from a group consisting of hydrogen, a substituted or unsubstituted aryl group having 6 to 30 carbon atoms, and a substituted or unsubstituted heteroaryl group having 5 to 30 carbon atoms.

According to one embodiment of the present disclosure, when a substituent is present in each of L₁, L₂, L₃, Ar₁, Ar₂ and Ar₃, each of the substituents may independently represent one selected from a group consisting of deuterium, an aralkyl group having 6 to 30 carbon atoms, an aryl group having 6 to 30 carbon atoms, a heteroaryl group having 5 to 30 carbon atoms, a heteroarylalkyl group having 5 to 30 carbon atoms, an alkoxy group having 1 to 30 carbon atoms, an alkylsilyl group having 1 to 30 carbon atoms, an arylsilyl group having 6 to 30 carbon atoms, and an aryloxy group having 6 to 30 carbon atoms.

According to one embodiment of the present disclosure, a “single bond” means that both opposing components around each of L₁, L₂ and L₃ in the Chemical Formula 1 directly bind to each other under absence of each of L₁, L₂ and L₃ in the Chemical Formula 1.

According to one embodiment of the present disclosure, the A ring or the B ring may refer to a monocyclic or polycyclic ring structure including a 5-membered and/or 6-membered carbocyclic or heterocyclic ring and may be a substituted or unsubstituted aryl group having 5 to 30 carbon atoms or a substituted or unsubstituted heteroaryl group having 5 to 30 carbon atoms.

According to one embodiment of the present disclosure, when one of Ar₁, Ar₂ and Ar₃ in the compound represented by the Chemical Formula 1 is the metallocene (in one example, ferrocene), the metallocene (in one example, ferrocene) may react with oxygen and moisture and thus be modified into a different structure. Thus, via the reaction, the metallocene may capture the oxygen and moisture penetrating into the device or may reduce a diffusion rate thereof in the device to prevent deterioration of device characteristics.

According to one embodiment of the present disclosure, in the compound represented by the Chemical Formula 1, when each of Ar₁, Ar₂ and Ar₃ is an aryl group or a heteroaryl group other than the metallocene (in one example, ferrocene), each of Ar₁, Ar₂ and Ar₃ may independently represent an aryl group of 3 or smaller rings or a heteroaryl group of 3 or smaller rings. In this case, at a low molecular weight, the compound represented by the Chemical Formula 1 may have a high glass transition temperature (Tg) such that a deposition temperature thereof may be lowered, thereby improving thermal stability of the compound during the deposition and in an operation of the device. For example, each of Ar₁, Ar₂ and Ar₃ may independently represent a phenyl group, a biphenyl group, a naphthyl group, an anthracenyl group, a phenanthrenyl group, a carbazolyl group, a pyridinyl group, a dibenzofuranyl group, a dibenzothiophenyl group, a pyrimidinyl group, a quinolinyl group, an isoquinolinyl group, a benzooxyzolyl group, a benzothiazolyl group, a benzoimidazolyl group, or a combination thereof. However, the present disclosure is not limited thereto.

According to one embodiment of the present disclosure, in the compound represented by the Chemical Formula 1, when each of Ar₁, Ar₂ and Ar₃ is an aryl group or a heteroaryl group other than the metallocene (in one example, ferrocene), each of Ar₁, Ar₂ and Ar₃ may independently represent not hydrogen, a phenyl group, a biphenyl group, or a terphenyl group but a naphthyl group, an anthracenyl group, a phenanthrenyl group, a carbazolyl group, a dibenzofuranyl group, or a dibenzothiophenyl group as a structurally planar fused polycyclic substituent having a high molecular weight. In this case, a bond between molecules becomes stronger, such that a volume decreases and the molecular weight increases, thereby increasing an overall density of the molecules, resulting in excellent refractive index and oxygen capture effect.

According to one embodiment of the present disclosure, the compound represented by the Chemical Formula 1 may be one selected from following compounds. The following compounds may further have a substituent.

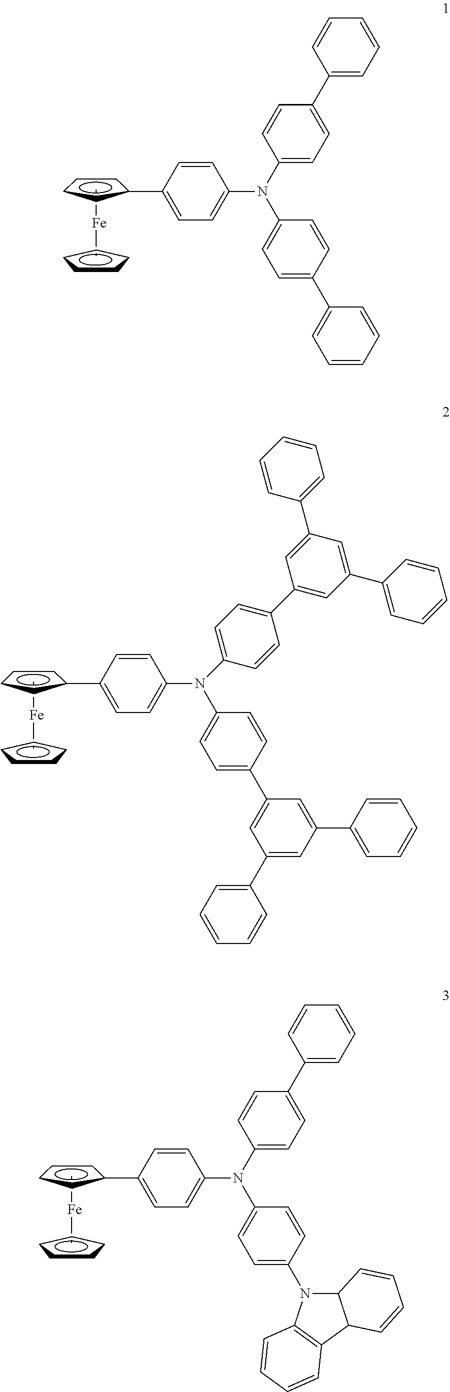

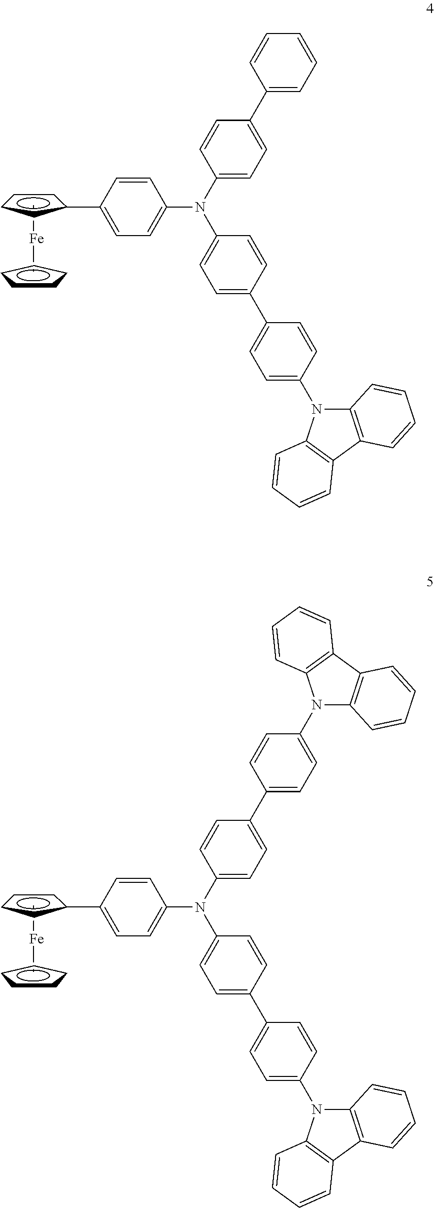

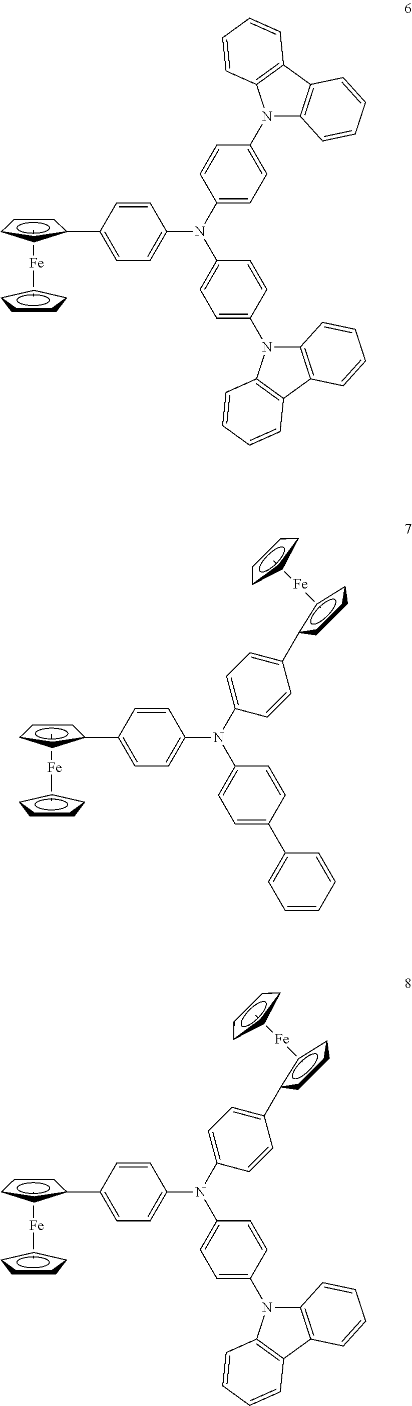

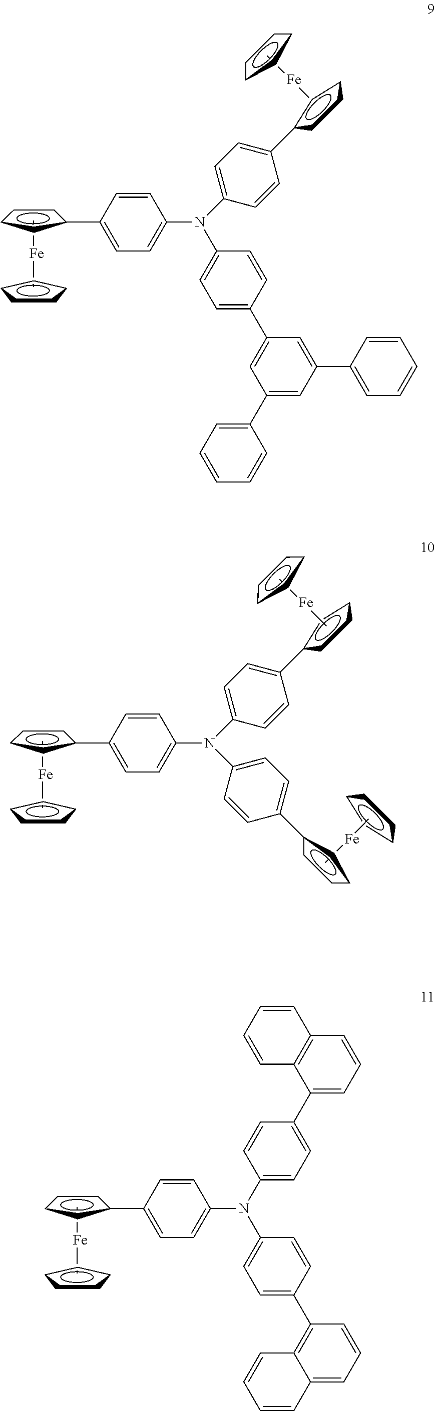

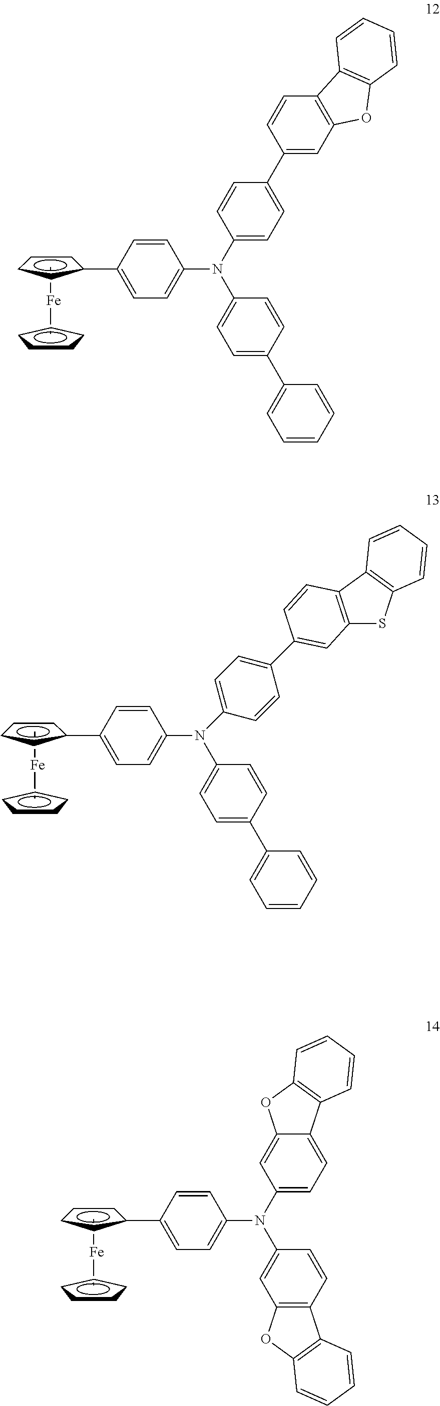

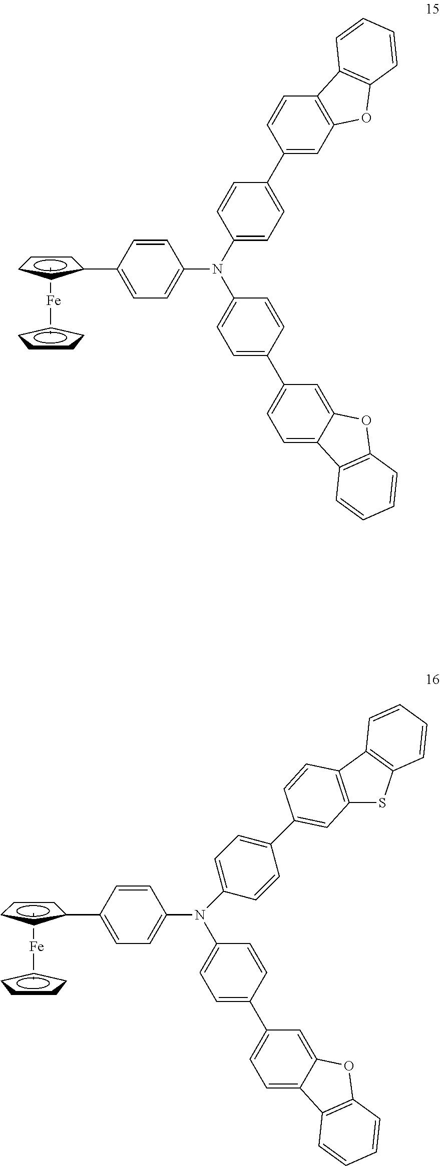

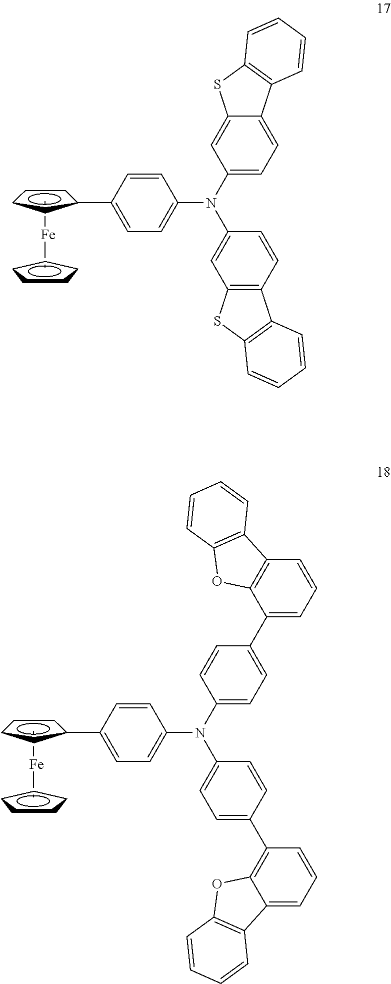

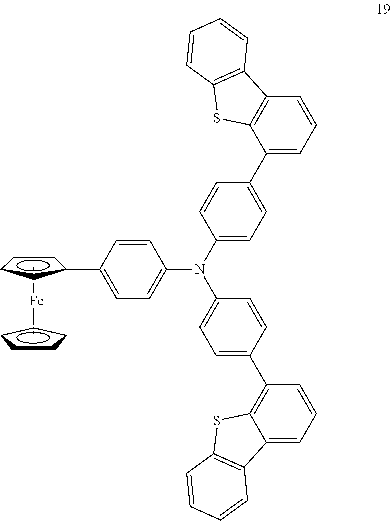

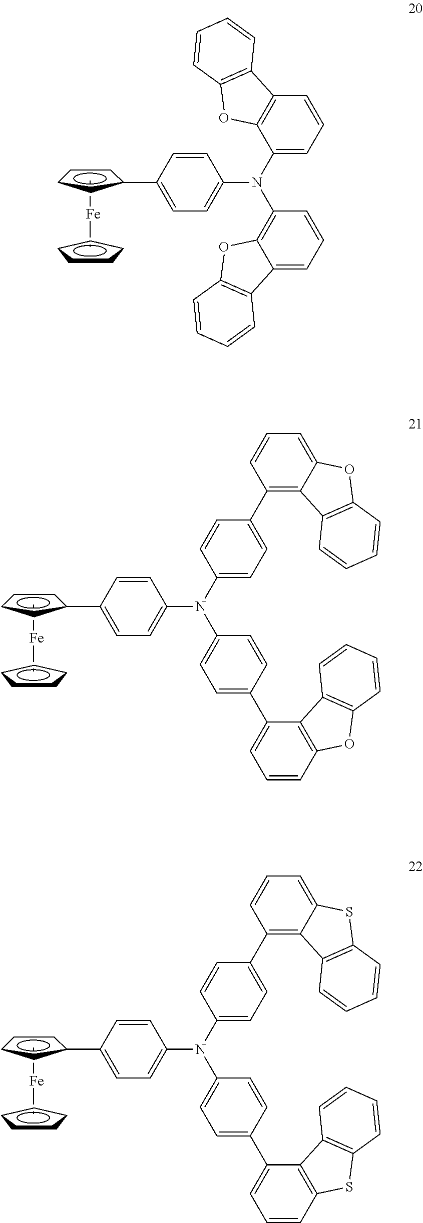

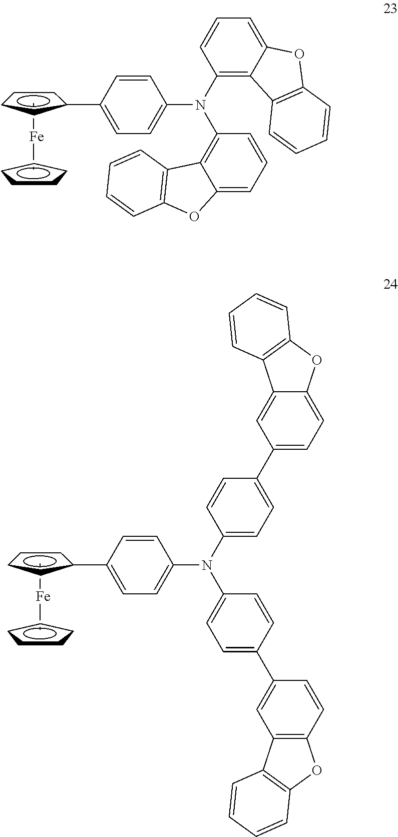

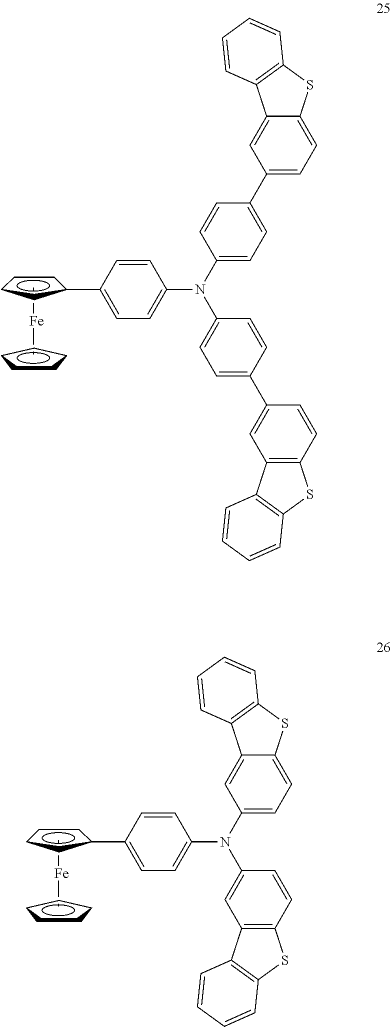

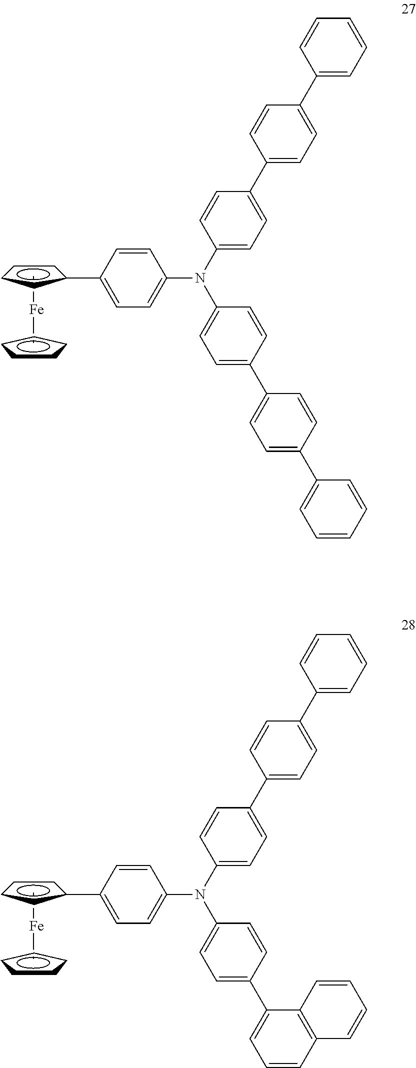

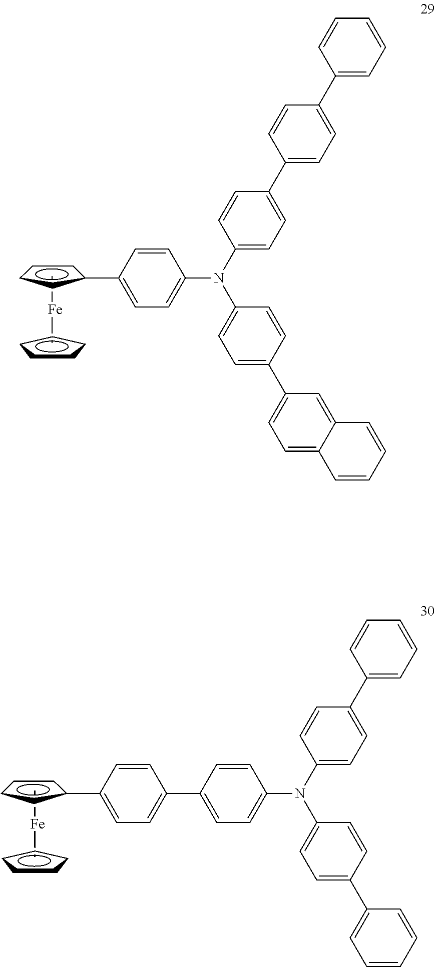

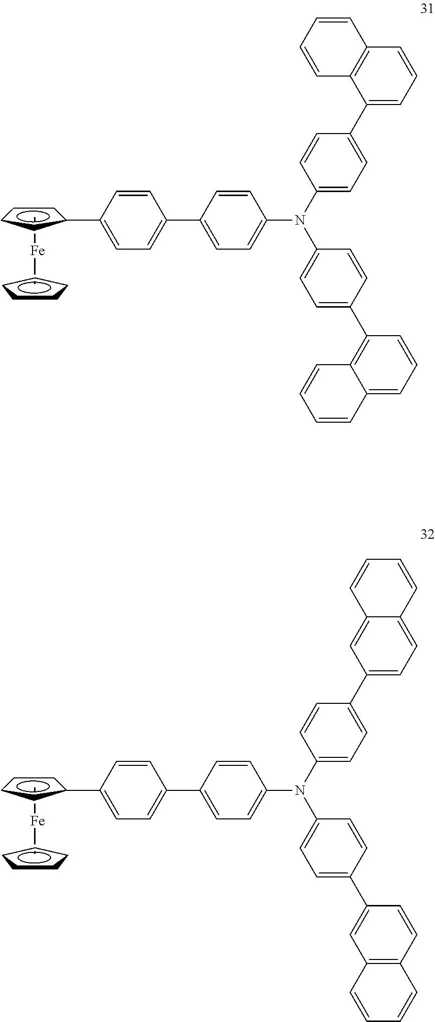

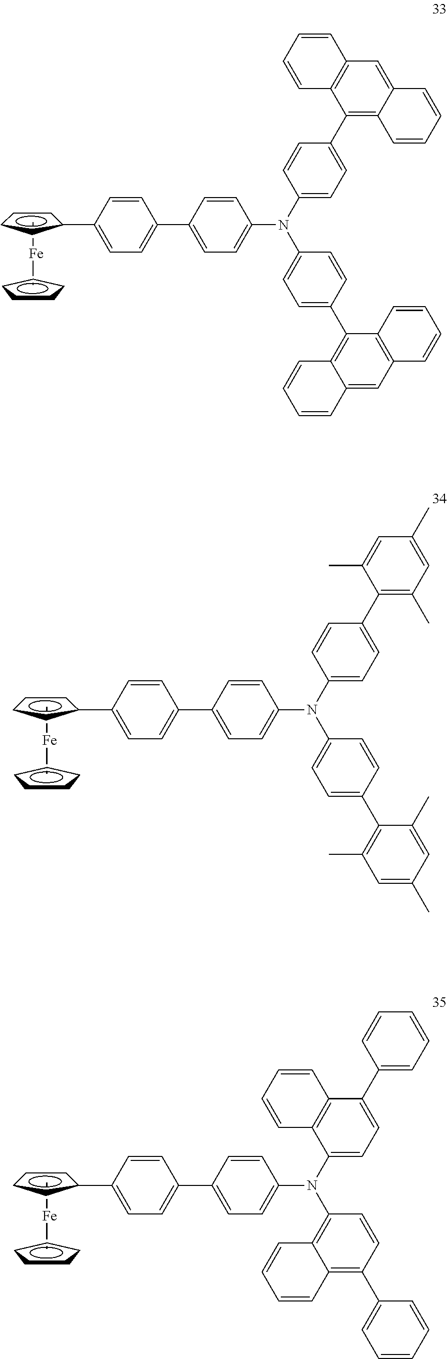

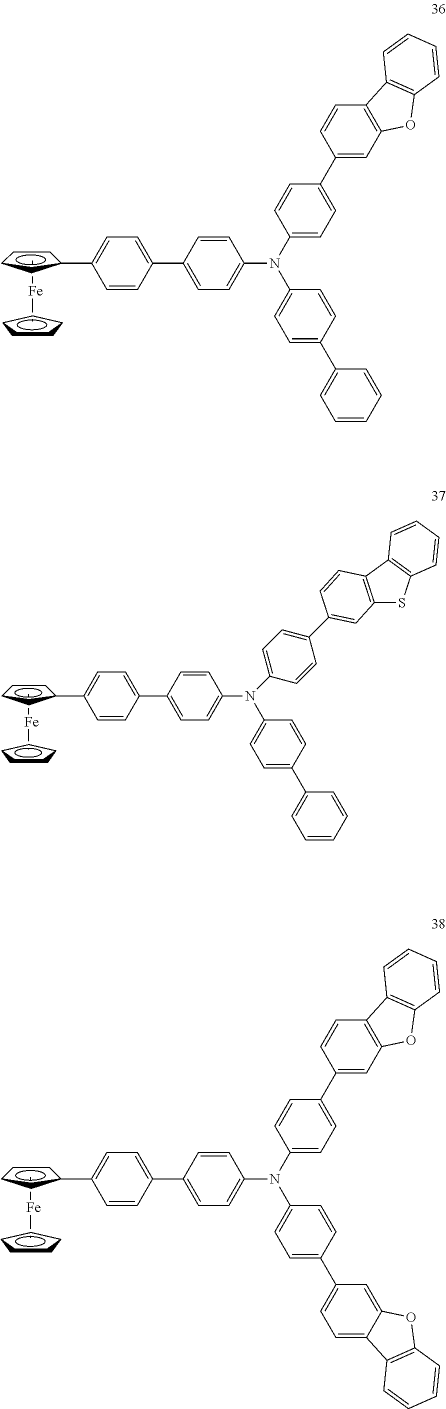

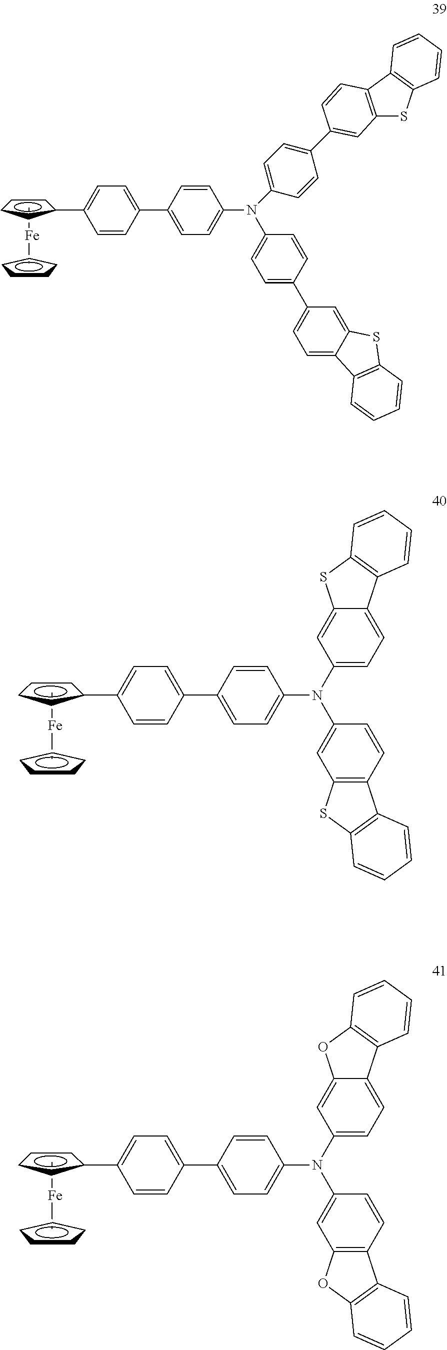

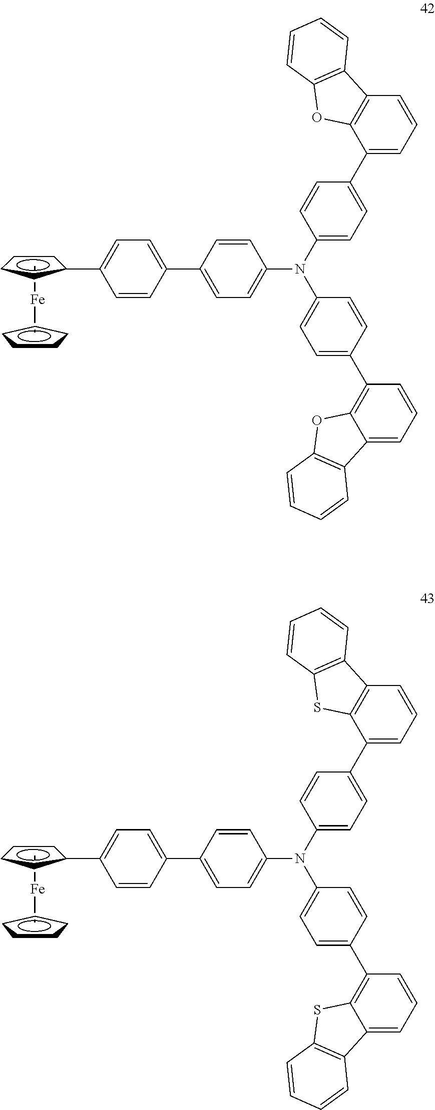

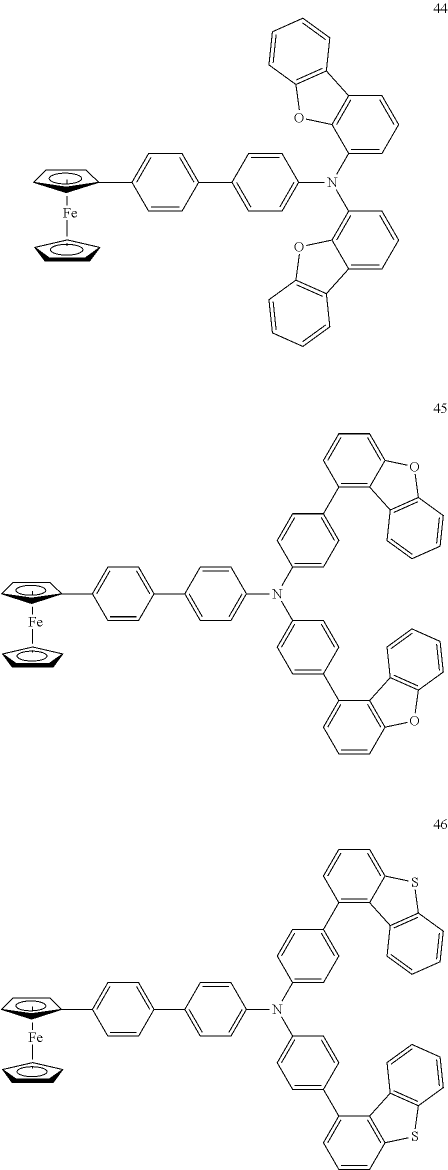

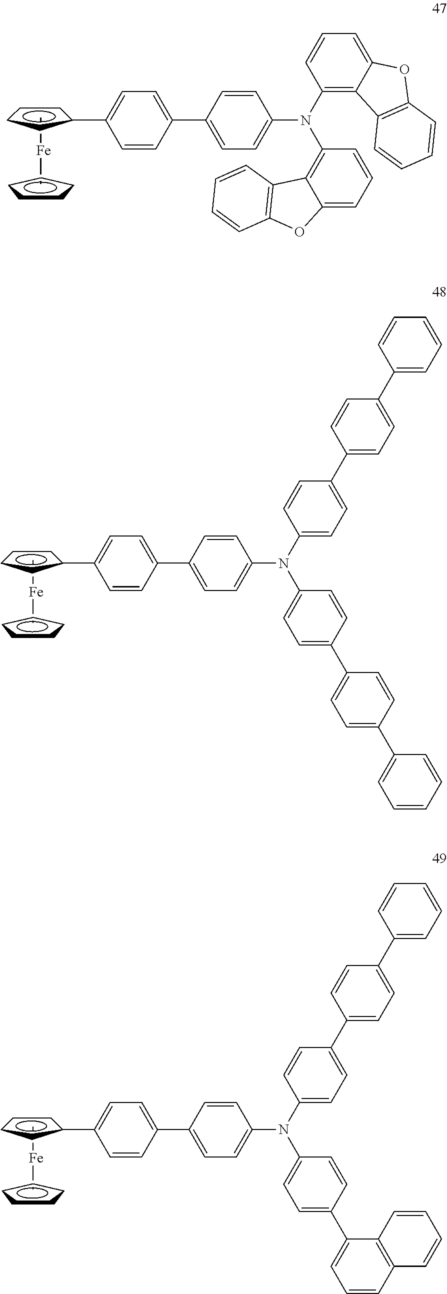

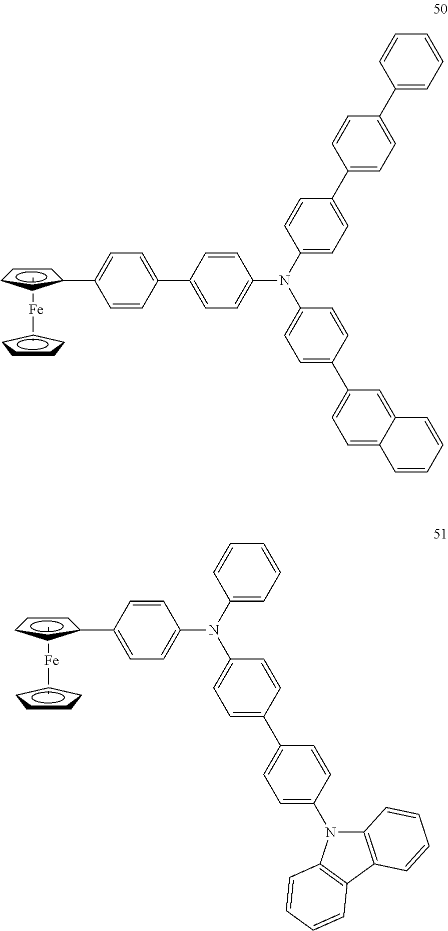

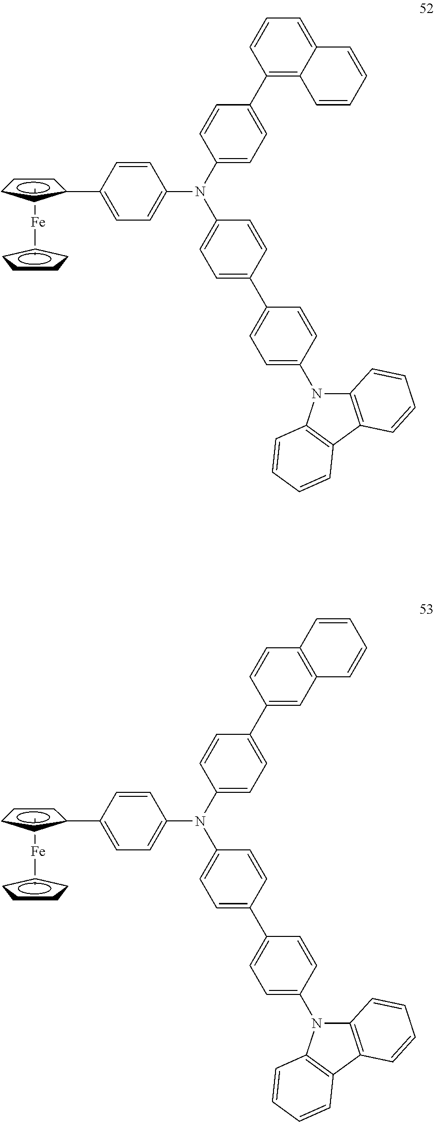

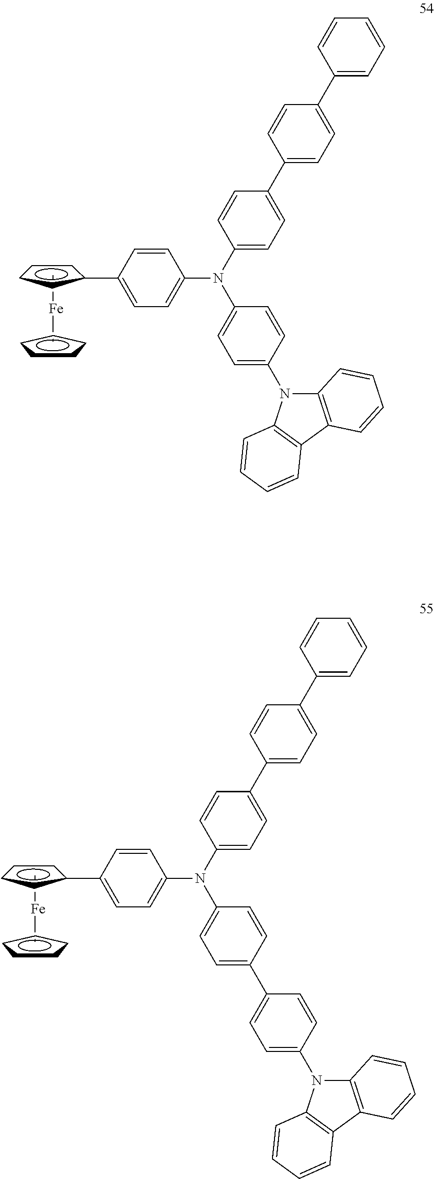

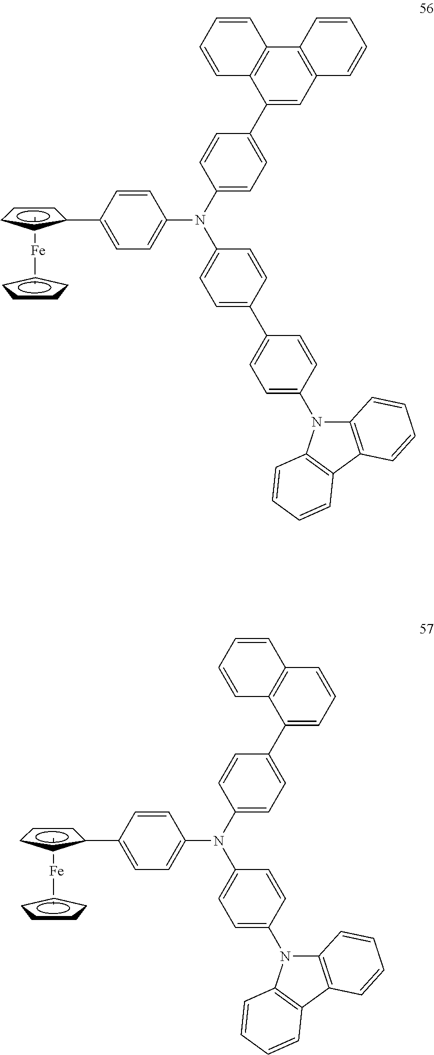

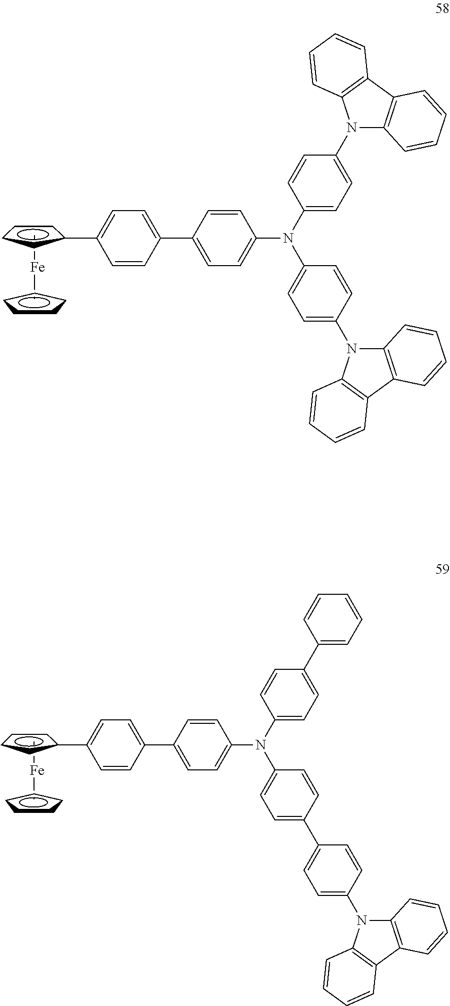

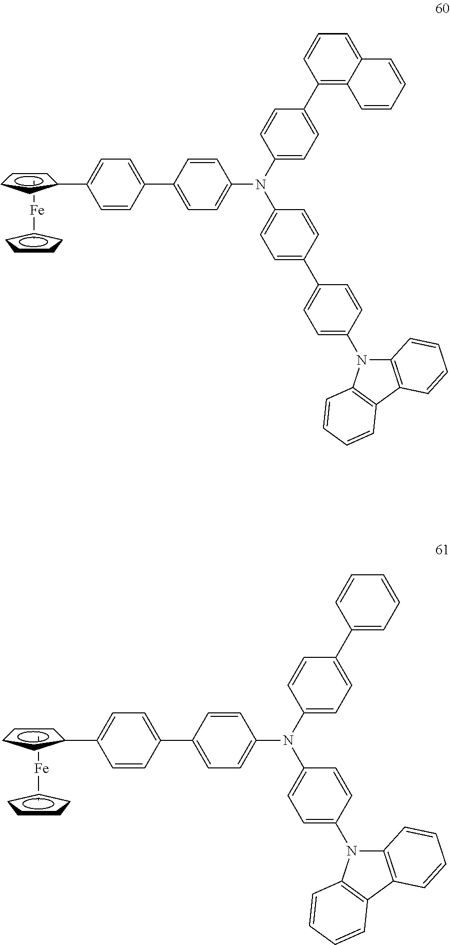

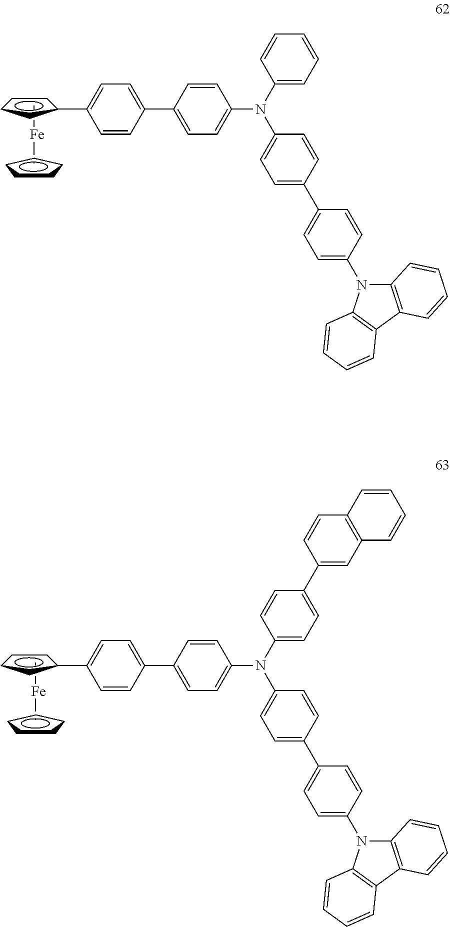

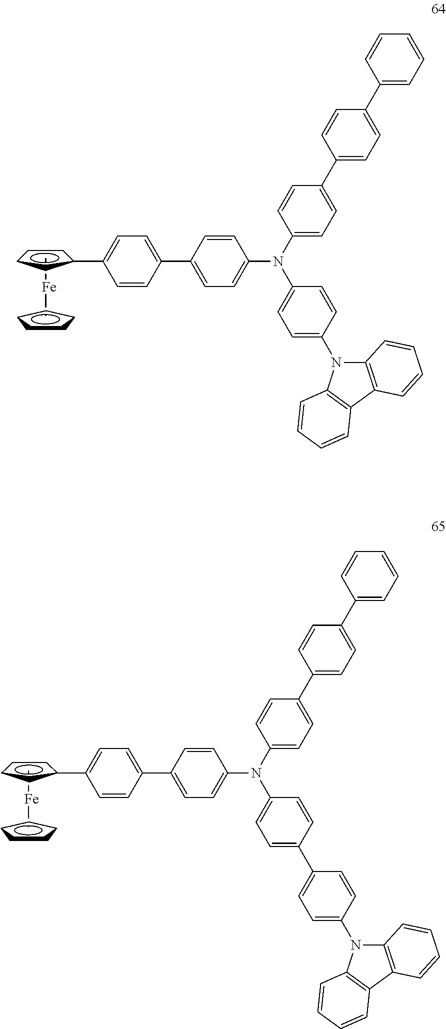

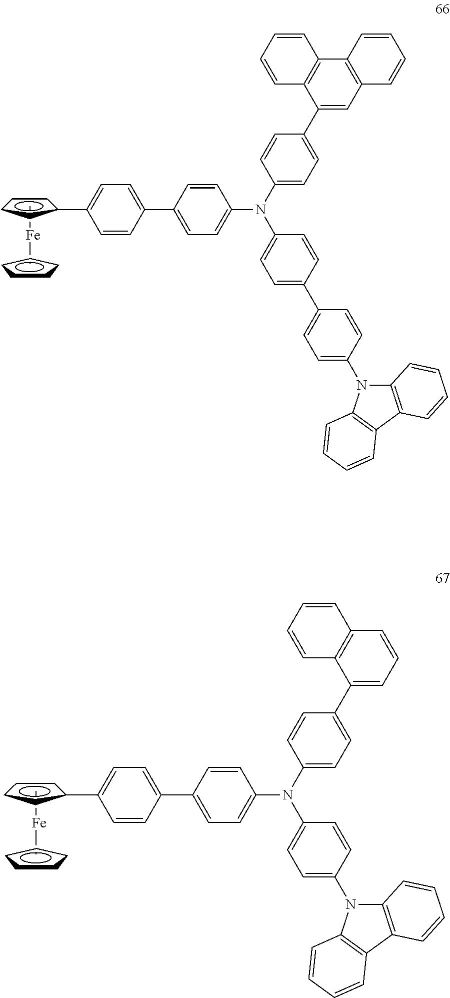

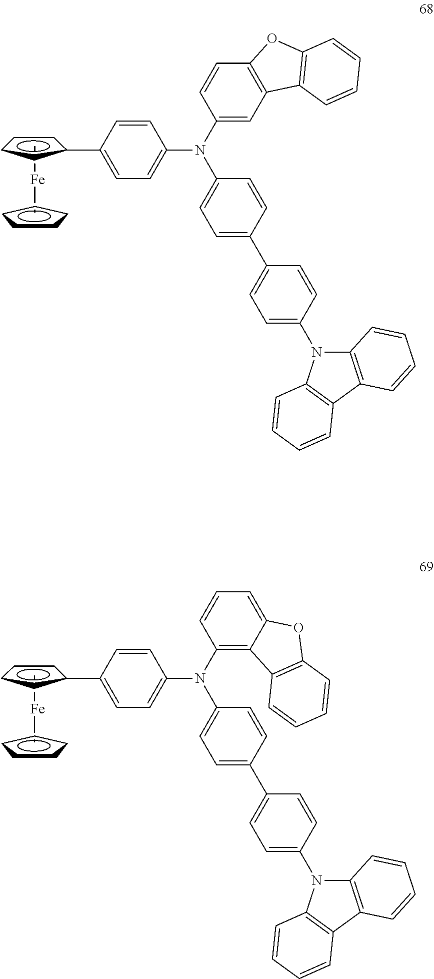

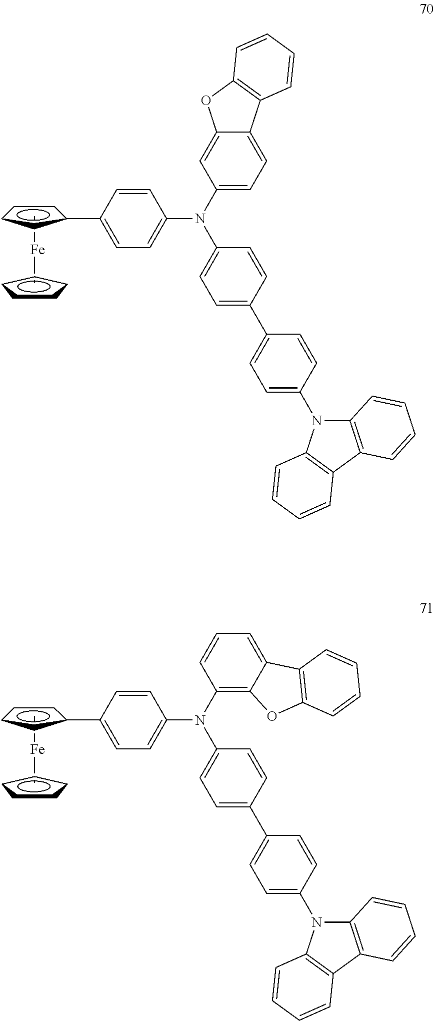

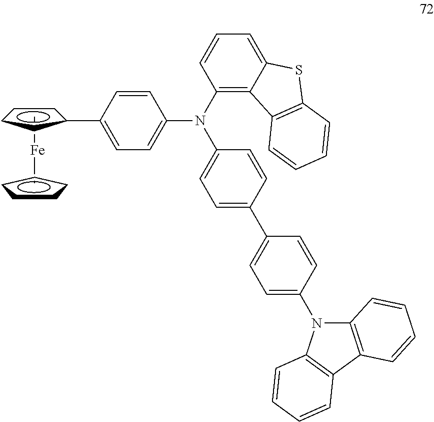

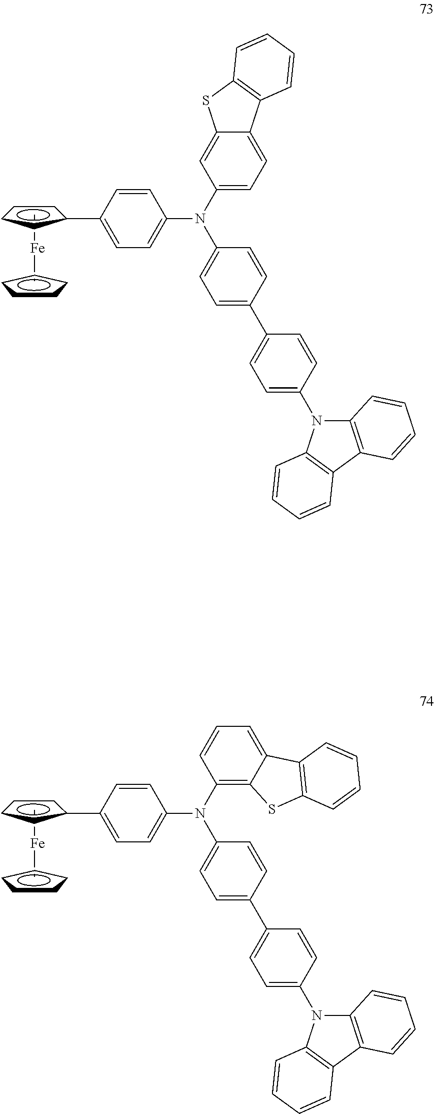

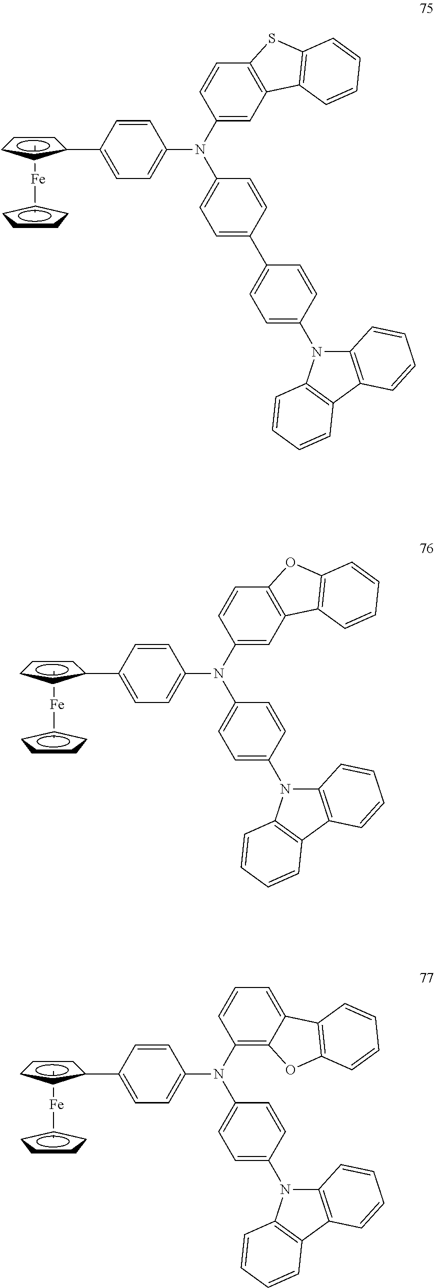

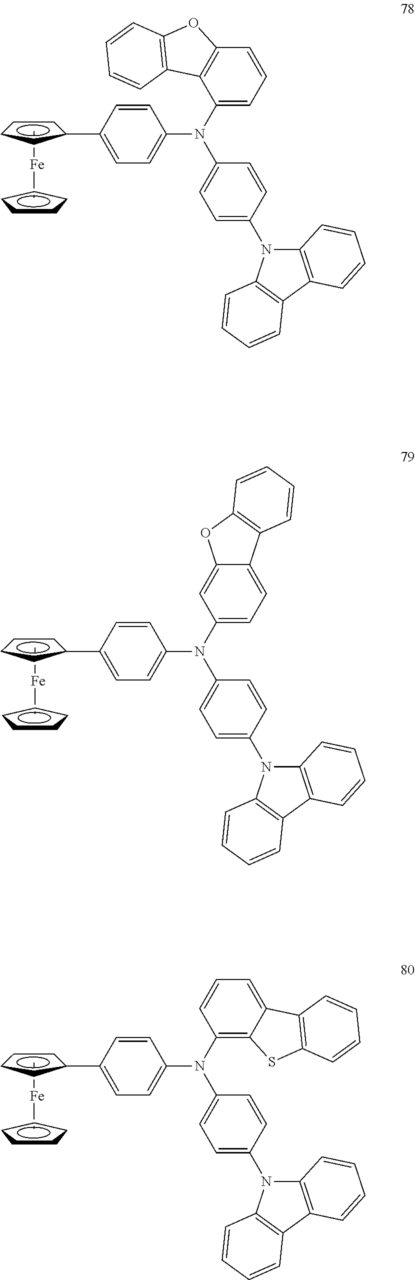

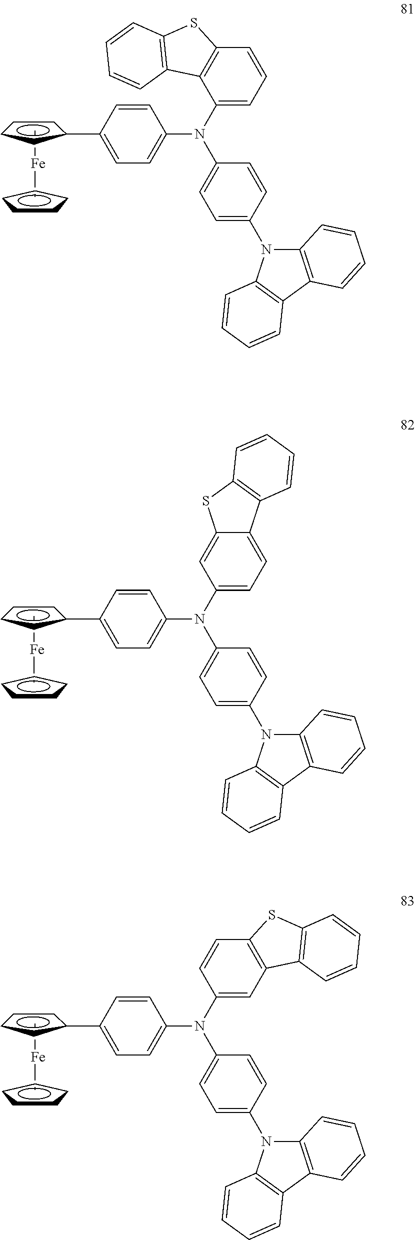

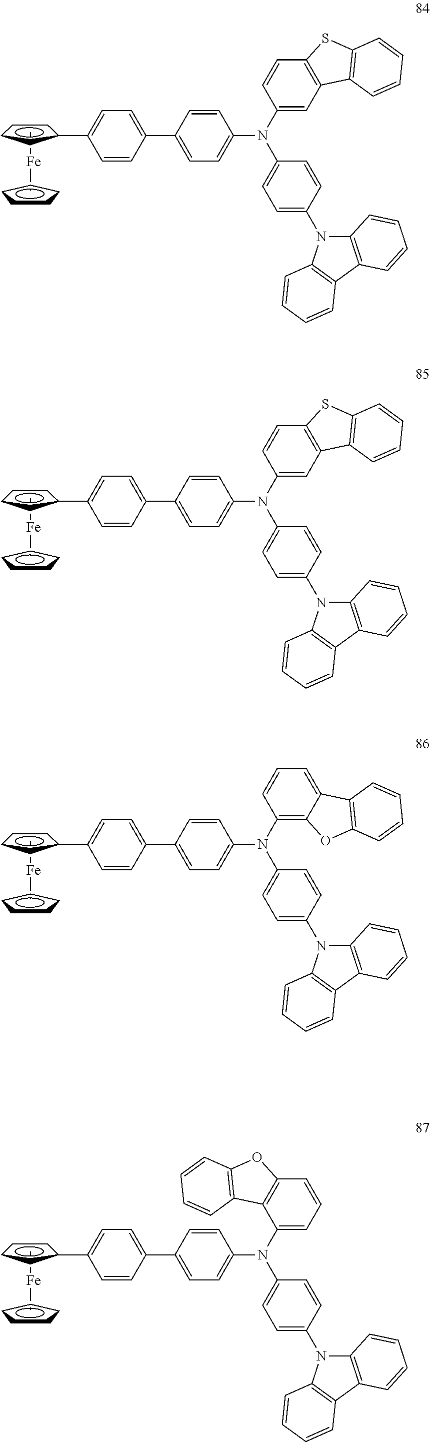

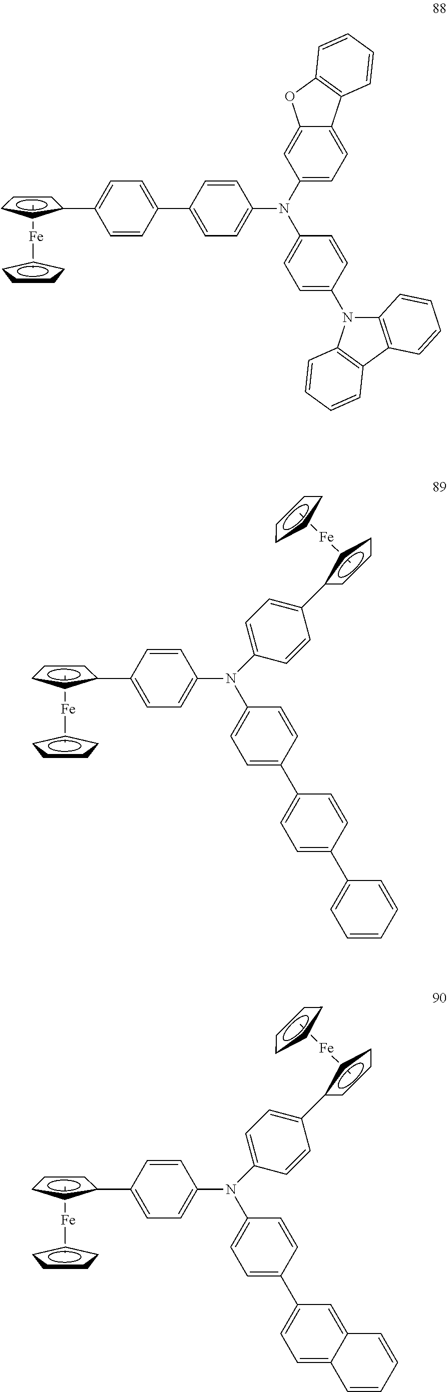

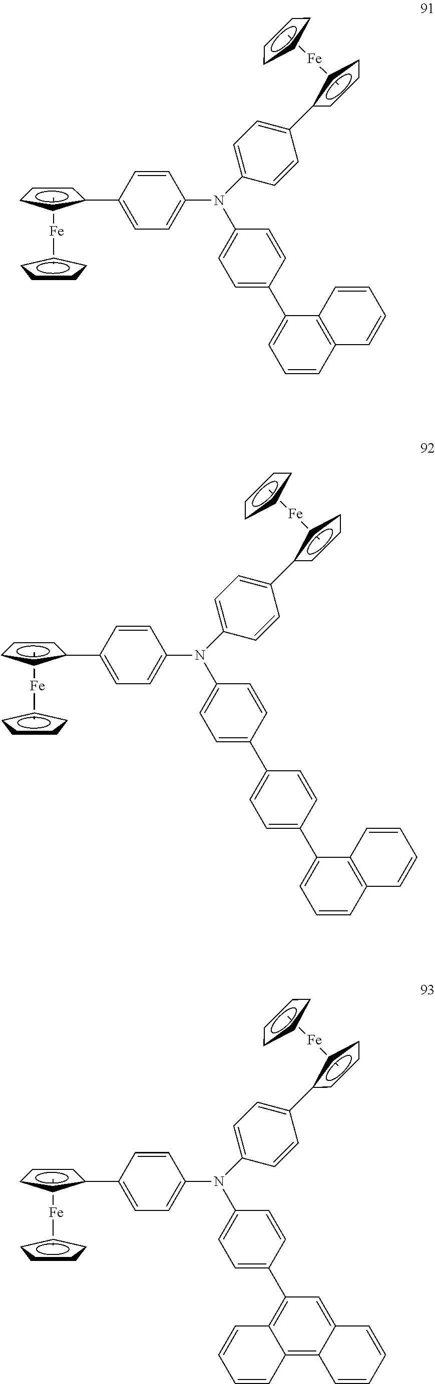

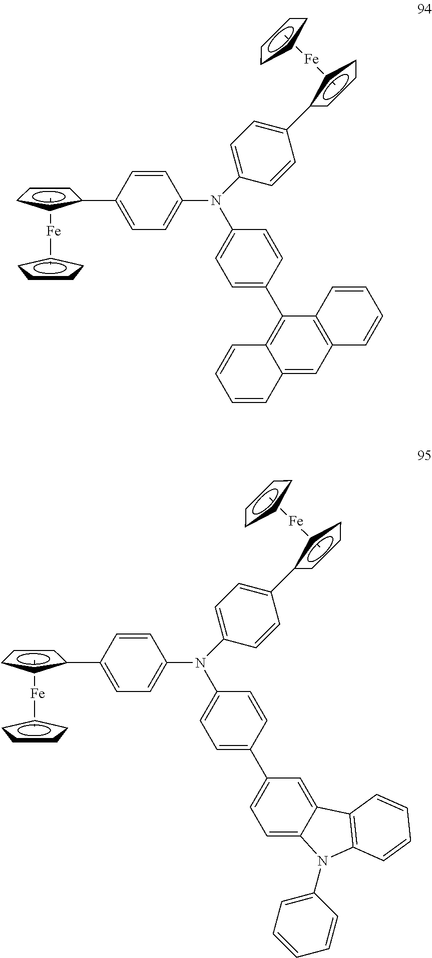

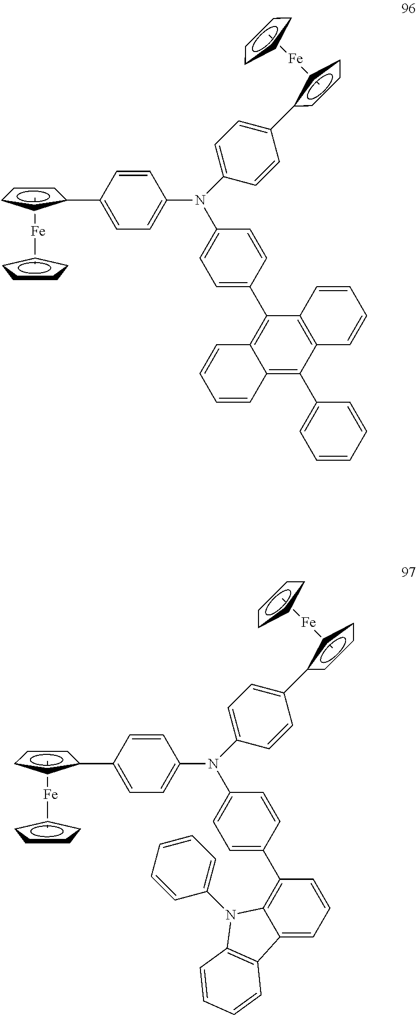

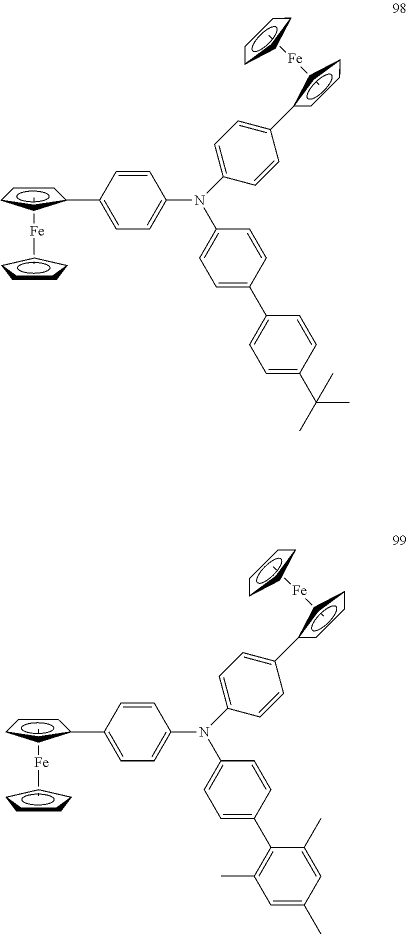

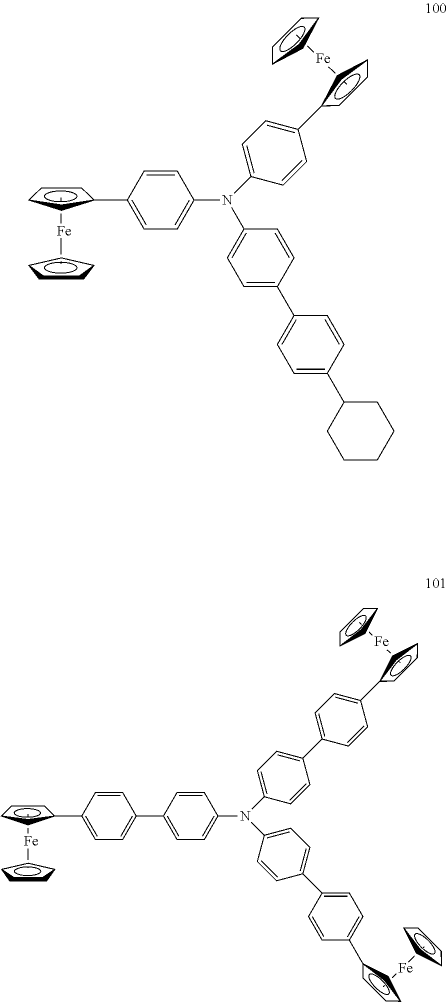

The organic light-emitting device according to an embodiment of the present disclosure includes first electrode; a second electrode facing the first electrode; and one or more organic layers between the first electrode and the second electrode, wherein one or more capping layers are disposed on a surface of the first electrode or the second electrode, wherein at least one of the capping layers includes the organic compound represented by chemical formula 1 as described above.

An organic material layer of an organic light-emitting device according to one embodiment of the present disclosure may include at least one of a hole injection layer, a hole transport layer, an electron blocking layer, a light-emitting layer, a hole blocking layer, an electron transport layer, or an electron injection layer. The organic material layer may additionally include a charge generation layer, an auxiliary hole transport layer, an auxiliary light-emitting layer, an auxiliary electron transport layer, etc.

For example, the organic light-emitting device may have a structure in which a first electrode (anode), a hole injection layer (HIL), a hole transport layer (HTL), an electron blocking layer (EBL), a light-emitting layer (EML), a hole blocking layer (HBL), an electron transport layer (ETL), an electron injection layer (EIL), and a second electrode (cathode) are sequentially stacked.

For example, the first electrode may include a transparent and highly conductive material such as indium tin oxide (ITO), indium zinc oxide (IZO), tin oxide (SnO₂), and zinc oxide (ZnO).

The hole injection layer or hole transport layer compound is not specifically limited. Any compound may be used as the hole injection layer or hole transport layer compound as long as it is generally used as the hole injection layer or hole transport layer compound. Non-limiting examples of the hole injection layer or hole transport layer compound may include a phthalocyanine derivative, a porphyrin derivative, a triarylamine derivative and an indolocarbazole derivative. For example, non-limiting examples of the hole injection layer or hole transport layer compound may include 1,4,5,8,9,11-hexaazatriphenylene-hexacarbonitrile (HAT-CN), copper phthalocyanine (CuPc), 4,4′,4″-tris(3-methylphenyl)amino) triphenylamine (m-MTDATA), 4,4′,4″-tris(3-methylphenylamino)phenoxybenzene (m-MTDAPB), 4,4′,4″-tri(N-carbazolyl)triphenylamine (TCTA), 4,4′,4″-tris(N-(2-naphthyl)-N-phenylamino)-triphenylamine (2-TNATA), N4,N4,N4′,N4′-tetra([1,1′-biphenyl]-4-yl)-[1,1′-biphenyl]-4,4′-diamine, bis(N-(1-naphthyl-n-phenyl))benzidine (α-NPD), N,N′-di(naphthalen-1-yl)-N,N′-biphenyl-benzidine (NPB) or N,N′-biphenyl-N,N′-bis(3-methylphenyl)-1,1′-biphenyl-4,4′-diamine (TPD), etc.

The compound included in the light-emitting layer is not specifically limited, and any compound may be used as the compound included in the light-emitting layer as long as it is generally used as the light-emitting layer compound. A single light-emitting compound or a light-emitting host compound may be used as the light-emitting layer compound.

Examples of the light-emitting compound of the light-emitting layer may include compounds that may cause light emission via phosphorescence, fluorescence, thermally-activated delayed fluorescence, i.e., TADF (also referred to as E-type delayed fluorescence), triplet-triplet quenching, or a combination of these processes. However, the present disclosure is not limited thereto. The light-emitting compound may be selected from a variety of materials depending on a desired color to be rendered. Non-limiting examples of the light-emitting compound may include condensed cyclic derivatives such as phenanthrene, anthracene, pyrene, tetracene, pentacene, perylene, naphthopyrene, dibenzopyrene, rubrene, and chrysene, a benzoxazole derivative, a benzothiazole derivative, a benzoimidazole derivative, a benzotriazole derivative, an oxazole derivative, a oxadiazole derivative, a thiazole derivative, a imidazole derivative, a thiadiazole derivative, a triazole derivative, a pyrazoline derivative, a stilbene derivative, a thiophene derivative, a tetraphenylbutadiene derivative, a cyclopentadiene derivative, a bisstyryl derivative, a bisstyryl arylene derivative, a diazindacene derivative, a furan derivative, a benzofuran derivative, a isobenzofuran derivative, a dibenzofuran derivative, a coumarin derivative, a dicyanomethylenepyran derivative, a dicyanomethylenethiopyran derivative, a polymethine derivative, a cyanine derivative, a oxobenzoanthracene derivative, an xanthene derivative, a rhodamine derivative, a fluorescein derivative, a pyrylium derivative, a carbostyryl derivative, a acridine derivative, a oxazine derivative, a phenylene oxide derivative, a quinacridone derivative, a quinazoline derivative, a pyrrolopyridine derivative, a furopyridine derivative, a 1,2,5-thiadiazolopyrene derivative, a pyromethene derivative, a perinone derivative, a pyrrolopyrrole derivative, a squaryllium derivative, a biolanthrone derivative, a phenazine derivative, a acridone derivative, a deazaflavin derivative, a fluorene derivative, a benzofluorene derivative, an aromatic boron derivative, an aromatic nitrogen boron derivative, and a metal complex (complex in which a metal such as Ir, Pt, Au, Eu, Ru, Re, Ag, and Cu binds to a heteroaromatic ring ligand). For example, non-limiting examples of the light-emitting compound may include N1,N1,N6,N6-tetrakis(4-(1-silyl)phenyl)pyrene-1,6-diamine, 2,12-di-tert-butyl-5,9-bis(4-(tert-butyl)phenyl)-7-(3,5-di-tert-butylphenyl)-5,9-dihydro-5,9-diaza-13b-boranaphtho[3,2,1-de]anthracene (t-DABNA-dtB), (PtOEP), Ir(ppy)₃, Ir(ppy)₂(acac), Ir(mppy)₃, Ir(PPy)₂(m-bppy), BtpIr(acac), Ir(btp)₂(acac), Ir(2-phq)₃, Hex-Ir(phq)₃, Ir(fbi)₂(acac), fac-Tris(2-(3-p-xylyl)phenyl)pyridine iridium(III), Eu(dbm)₃(Phen), Ir(piq)₃, Ir(piq)₂(acac), Ir(Fliq)₂(acac), Ir(Flq)₂(acac), Ru(dtb-bpy)₃-2(PF6), Ir(BT)₂(acac), Ir(DMP)₃, Ir(Mphq)₃IR(phq)₂tpy, fac-Ir(ppy)₂Pc, Ir(dp)PQ₂, Ir(Dpm)(Piq)₂, Hex-Ir(piq)₂(acac), Hex-Ir(piq)₃, Ir(dmpq)₃, Ir(dmpq)₂(acac), FPQIrpic, FIrpic, etc.

As a host compound of the light-emitting layer, a light-emitting host, a hole-transporting host, an electron-transporting host, or a combination thereof may be used. Non-limiting examples of a light-emitting host compound may include condensed cyclic derivatives such as anthracene and pyrene, bisstyryl derivatives such as a bisstyryl anthracene derivative and a distyrylbenzene derivative, a tetraphenylbutadiene derivative, a cyclopentadiene derivative, a fluorene derivative, a benzofluorene derivative, a N-phenylcarbazole derivative, and a carbazonitrile derivative. Non-limiting examples of the hole-transporting host material may include a carbazole derivative, a dibenzofuran derivative, a dibenzothiophene derivative, a triarylamine derivative, an indolocarbazole derivative, and a benzoxazinophenoxazine derivative. Non-limiting examples of the electron-transporting host material may include a pyridine derivative, a triazine derivative, a phosphorus oxide derivative, a benzofuropyridine derivative, and a dibenzoxacillin derivative. For example, the non-limiting examples of the electron-transporting host material may include 9,10-bis(2-naphthyl)anthracene (ADN), tris(8-hydroxyquinolinato)aluminum (Alq₃), Balq (8-hydroxyquinoline beryllium salt), DPVBi (4,4′-bis(2,2-biphenylethenyl)-1,1′-biphenyl), spiro-DPVBi (spiro-4,4′-bis(2,2-biphenylethenyl)-1, l′-biphenyl), LiPBO (2-(2-benzooxazolyl)-phenol lithium salt), bis(biphenylvinyl)benzene, an aluminum-quinoline metal complex, and metal complexes of imidazole, thiazole and oxazole, etc.

The electron blocking layer (EBL) may be formed between the hole transport layer and the light-emitting layer. The electron blocking layer compound is not specifically limited, and any compound may be used as the electron blocking layer compound as long as it is commonly used as the electron blocking layer compound. For example, the electron blocking layer compound may include N-phenyl-N-(4-(spiro[benzo[d,c]anthracene-7,9′-fluoren]-2′-yl)phenyl)dibenzo[b,d] furan-4-amine), etc.

The electron injection layer or electron transport layer compound is not specifically limited, and any compound may be used as the electron injection layer or electron transport layer compound as long as it is generally used as the electron injection layer or electron transport layer compound. Non-limiting examples of the electron injection layer or electron transport layer compounds may include a pyridine derivative, a naphthalene derivative, a anthracene derivative, a phenanthroline derivative, a perinone derivative, a coumarin derivative, a naphthalimide derivative, a anthraquinone derivative, a diphenoquinone derivative, a diphenylquinone derivative, a perylene derivative, a oxadiazole derivative, a thiophene derivative, a triazole derivative, a thiadiazole derivative, a metal complex of an oxine derivative, a quinolinol-based metal complex, a quinoxaline derivative, a polymer of the quinoxaline derivative, a benzazole compound, a gallium complex, a pyrazole derivative, a perfluorinated phenylene derivative, a triazine derivative, a pyrazine derivative, a benzoquinoline derivative, a imidazopyridine derivative, a borane derivative, a benzoimidazole derivative, a benzoxazole derivative, a benzothiazole derivative, a quinoline derivative, an oligopyridine derivative such as terpyridine, a bipyridine derivative, a terpyridine derivative, a naphthyridine derivative, a aldazine derivative, a carbazole derivative, an indole derivative, a phosphorus oxide derivative, a bisstyryl derivative, a quinolinol-based metal complex, a hydroxyazole-based metal complex, an azomethine-based metal complex, a tropolone-based metal complex, a flavonol-based metal complex, a benzoquinoline-based metal complex, metal salts, etc. The materials as described above may be used singly, or may also be used as mixtures with other materials. For example, non-limiting examples of the electron injection layer or electron transport layer compounds may include 2-(4-(9,10-di(naphthalen-2-yl)anthracen-2-yl)phenyl)-1-phenyl-1H-benzo[d]imidazole, tris(8-hydroxyquinolinato)aluminum (Alq₃), LiF, Liq, LizO, BaO, NaCl, and CsF.

The hole blocking layer (HBL) may be formed between the electron transport layer and the light-emitting layer. The hole blocking layer compound is not specifically limited, and any compound may be used as the hole blocking layer compound as long as it is generally used as the hole blocking layer compound. For example, the hole blocking layer compound may include pyrimidine derivatives, etc.

The second electrode (cathode) may include lithium (Li), aluminum (Al), aluminum-lithium (Al—Li), calcium (Ca), magnesium (Mg), magnesium-indium (Mg—In), or magnesium-silver (Mg—Ag). Moreover, in a top-emission type organic light-emitting device, indium tin oxide (ITO) or indium zinc oxide (IZO) may be used for the second electrode (cathode) and thus may constitute a transparent cathode through which light can transmit.

One or more capping layers may be located on a surface of the first electrode or the second electrode, Preferably, the capping layer may be located on the surface of the second electrode. The capping layer may include at least one compound selected from the compounds represented by the Chemical Formula 1 in accordance with the present disclosure.

The capping layer may include an additional capping layer compound.

The additional capping layer compound is not specifically limited, and any compound may be used as the additional capping layer compound as long as it is commonly used as the capping layer compound. Non-limiting examples of the capping layer compound may include an arylamine derivative such as a N4,N4′-bis[4-[bis(3-methylphenyl)amino]phenyl]-N4,N4′-diphenyl-[1,1′-biphenyl]-4,4′-diamine (DNTPD), a naphthalene derivative, an anthracene derivative, a phenanthrene derivative, a carbazole derivative, a pyridine derivative, a dibenzofuran derivative, a dibenzothiophene derivative, a pyrimidine derivative, a quinoline derivative, a isoquinoline derivative, a benzoxazole derivative, a benzothiazole derivative, a benzoimidazole derivative, hydroxyquinolinato)aluminum (Alq₃), LiF, Liq, Li₂O, BaO, NaCl, and CsF.

The organic light-emitting device according to one embodiment of the present disclosure may include a plurality of capping layers. In this regard, at least one of the plurality of capping layers or all of the plurality of capping layers may include at least one selected from the compounds represented by the Chemical Formula 1.

When the organic light-emitting device is stored for a long period of 6 months or larger, each of a lifetime (LT95) and current efficiency (Cd/A) of the device may be maintained at about 5%, 7%, 10%, and 20% of an initial measured value.

The organic light-emitting device according to one embodiment of the present disclosure may be embodied as a top emission or bottom emission type light-emitting device.

A thickness of the capping layer of the organic light-emitting device according to one embodiment of the present disclosure may be in a range of about 300 to 1500 Å, or about 500 to 1200 Å, or about 600 to 1000 Å.

In the organic light-emitting device according to an embodiment of the present disclosure, a density of the capping layer may be in a range of about 1.15 to 1.35 g/cm³, or about 1.2 to 1.3 g/cm³. Within this density range, device efficiency may be further improved.

The organic light-emitting device according to one embodiment of the present disclosure may be used for a display device.

The organic light-emitting device according to one embodiment of the present disclosure may be applied, as a light-emitting element, to a transparent display device, a mobile display device, a flexible display device, etc. However, the present disclosure is not limited thereto. The capping layer according to an embodiment exhibits high transmittance suitable for the transparent display device and has high tensile strength suitable for the flexible display device.

Hereinafter, a method for synthesizing the above compounds will be described based on representative examples. However, the method of synthesis of the compounds of the present disclosure is not limited to the following examples.

### SYNTHESIS EXAMPLE

### 1. Synthesis of Product 1

Product 1 may be synthesized as follows. However, the present disclosure is not limited thereto.

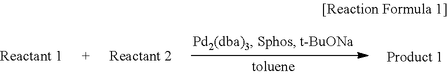

Reactant 1 (20 mmol), reactant 2 (22 mmol), t-BuONa (60 mmol), Pd₂(dba)₃ (1 mmol), Sphos (4 mmol) and toluene (300 mL) were added into a 500 mL flask under a nitrogen atmosphere, followed by stirring for 6 hours under a reflux condition. After completion of reaction, an organic layer was extracted therefrom using CH₂Cl₂ and water. The extracted layer in a solution state was treated with MgSO₄ to remove residual moisture therefrom and was concentrated under reduced pressure. Then, the concentrate was subjected to purification using column chromatography and then, recrystallization. Thus, Product 1 was obtained. The synthesis result of Product 1 is shown in Table 1 below.

TABLE 1

| | | Product | | |
|---|---|---|---|---|
| Reactant 1 | Reactant 2 | 1 | Yield | [M + H]+ |
| 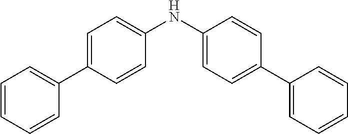 [SMILES: c1ccc(-c2ccc(Nc3ccc(-c4ccccc4)cc3)cc2)cc1] | 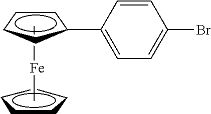 | Com- pound 1 | 10.3 g (71%) | 581.18 |
| 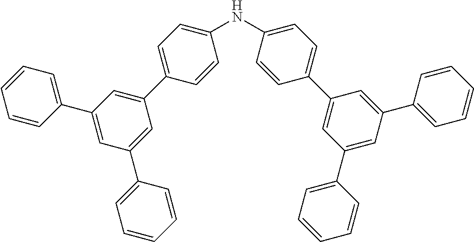 [SMILES: c1ccc(-c2cc(-c3ccccc3)cc(-c3ccc(Nc4ccc(-c5cc(-c6ccccc6)cc(-c6ccccc6)c5)cc4)cc3)c2)cc1] | 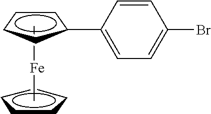 | Com- pound 2 | 10.9 g (66%) | 670.21 |
| 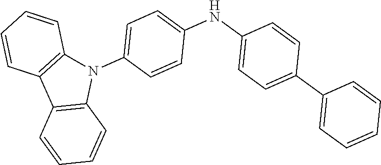 [SMILES: c1ccc(-c2ccc(Nc3ccc(-n4c5ccccc5c5ccccc54)cc3)cc2)cc1] | 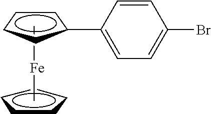 | Com- pound 3 | 11.9 g (70%) | 885.31 |
| 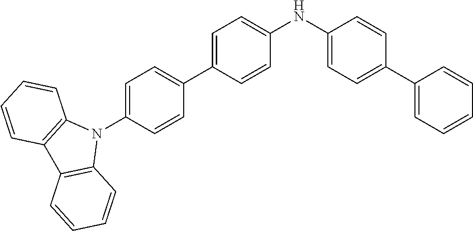 [SMILES: c1ccc(-c2ccc(Nc3ccc(-c4ccc(-n5c6ccccc6c6ccccc65)cc4)cc3)cc2)cc1] | 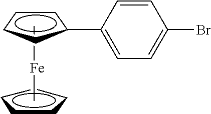 | Com- pound 4 | 10.1 g (68%) | 746.24 |
| 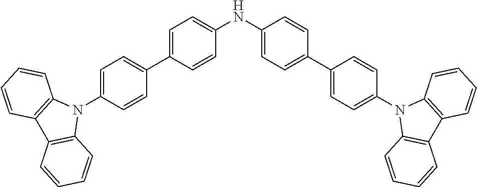 [SMILES: c1ccc2c(c1)c1ccccc1n2-c1ccc(-c2ccc(Nc3ccc(-c4ccc(-n5c6ccccc6c6ccccc65)cc4)cc3)cc2)cc1] | 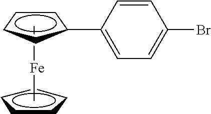 | Com- pound 5 | 11.8 g (65%) | 911.30 |
| 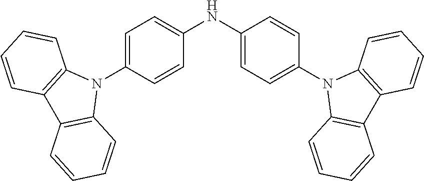 [SMILES: c1ccc2c(c1)c1ccccc1n2-c1ccc(Nc2ccc(-n3c4ccccc4c4ccccc43)cc2)cc1] | 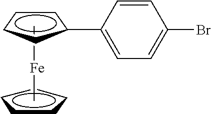 | Com- pound 6 | 10.6 g (70%) | 759.23 |

### 2. Synthesis of Product 2

Product 2 may be synthesized as follows. However, the present disclosure is not limited thereto.

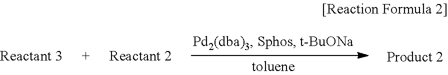

Reactant 3 (20 mmol), reactant 2 (42 mmol), t-BuONa (120 mmol), Pd₂(dba)₃ (1 mmol), Sphos (4 mmol) and toluene (300 mL) were added to a 500 mL flask under a nitrogen atmosphere, followed by stirring for 6 hours under a reflux condition. After completion of reaction, an organic layer was extracted therefrom using CH₂Cl₂ and water. The extracted layer in a solution state was treated with MgSO₄ to remove residual moisture therefrom and was concentrated under reduced pressure. Then, the concentrate was subjected to purification using column chromatography and then, recrystallization. Thus, Product 2 was obtained. The synthesis result of Product 2 is shown in Table 2 below.

TABLE 2

| Reactant 3 | Reactant 2 | Product 2 | Yield | [M + H]⁺ |
|---|---|---|---|---|
| 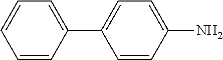 [SMILES: Nc1ccc(-c2ccccc2)cc1] | 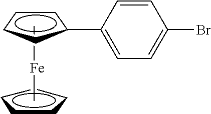 | Compound 7 | 10.3 g (75%) | 689.15 |
| 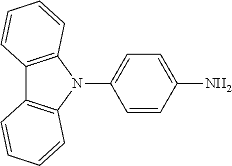 [SMILES: Nc1ccc(-n2c3ccccc3c3ccccc32)cc1] | 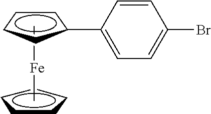 | Compound 8 | 10.9 g (70%) | 778.17 |
| 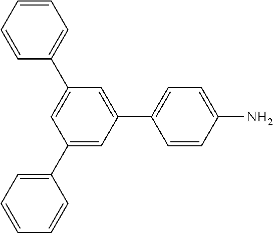 [SMILES: Nc1ccc(-c2cc(-c3ccccc3)cc(-c3ccccc3)c2)cc1] | 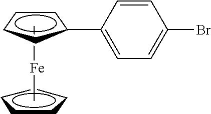 | Compound 9 | 11.9 g (71%) | 841.21 |

### 3. Synthesis of Product 3

Product 3 may be synthesized as follows. However, the present disclosure is not limited thereto.

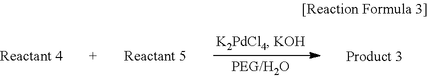

Reactant 4 (20 mmol), Reactant 5 (10 mmol), KOH (60 mmol), K₂PdCl₄ (0.2 mmol), and 40 mL of PEG/H₂O (10:1) were added to a 100 mL flask under a nitrogen atmosphere, followed by stirring for 2 hours at 80° C. After completion of reaction, an organic layer was extracted therefrom using CH₂Cl₂ and water. The extracted layer in a solution state was treated with MgSO₄ to remove residual moisture therefrom and was concentrated under reduced pressure. Then, the concentrate was subjected to purification using column chromatography and then, recrystallization. Thus, Product 3 was obtained. The synthesis result of Product 3 is shown in Table 3 below.

TABLE 3

| Reactant 4 | Reactant 5 | Product 3 | Yield | [M + H]⁺ |
|---|---|---|---|---|
| 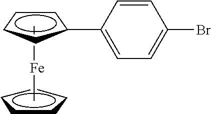 | 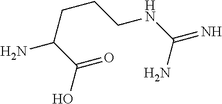 [SMILES: N=C(N)NCCCC(N)C(=O)O] | Compound 10 | 13.6 g (85%) | 797.11 |

### [Experimental Example 1] Experiment to Identify Oxygen and Moisture Capture Ability of Single Film

A single film for density measurement was fabricated using the compound in accordance with the present disclosure. Then, the single film for density measurement was analyzed using a high resolution X-ray diffractometer (available from PHILIPS Co.).

In order to analyze, a single film was fabricated by depositing a compound of the present disclosure to a thickness of 1000 Å on a glass substrate (0.7T) at a vacuum level of 9×10⁻⁷ Torr at a speed of 1 Å/sec.

The Compound 3 was used in the fabrication of the single film for evaluating the density and the optical property:

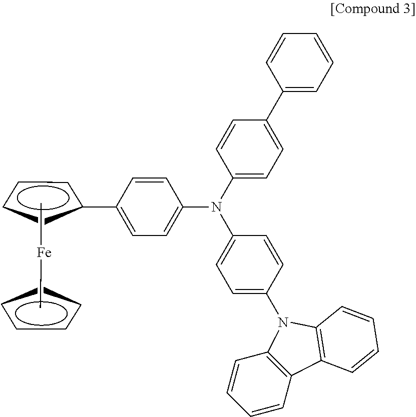

TABLE 4

| Material | Density (g/cm³) |
|---|---|
| Compound 3 | 1.26 |

Based on the Table 4, it was identified that when the compound of the present disclosure has high-density characteristics as the capping layer material.

Oxygen permeability and moisture permeability, etc. of the single film made of the compound of the present disclosure were identified in a following manner.

Moreover, an organic light-emitting device was manufactured with the compound in accordance with the present disclosure. Then, an operation voltage, luminous efficiency, external quantum efficiency (EQE), a lifetime, and stability of the device were identified. In order to identify the oxygen and moisture permeability of the single film, an experiment was conducted as follows.

### Present Example 1

The Compound 1 was vacuum deposited on a TAC (Tri-Acetyl Cellulose) film to form a single film of an area size of 5 cm×5 cm and a thickness of 2,000 Å. Measurement was conducted on the single film at 23° C. and 0% relative humidity using an oxygen permeability measuring device (OX-TRAN Model, available from AMETEK MOCON Co.).

### Present Examples 2 to 4

Single films of Present Examples 2 to 4 were formed in the same manner as in [Present Example 1] except that the Compound 7, Compound 6, and Compound 8 were used instead of the Compound 1, respectively.

### Comparative Examples 1 and 2

Single films of Comparative Examples 1 and 2 were formed in the same manner as in [Present Example 1] except that following Compound A and Compound B were used instead of Compound 1, respectively.

Table 5 below shows the performance comparison results of Present Examples 1 to 4 and Comparative Examples 1 and 2.

TABLE 5

| | | Oxygen permeability |
|---|---|---|
| | Compound | (cc/m² · day) |
| Present | 1 | 0.020 |
| Example 1 | | |
| Present | 7 | 0.005 |
| Example 2 | | |
| Present | 6 | 0.017 |
| Example 3 | | |
| Present | 8 | 0.004 |
| Example 4 | | |
| Comparative | Compound A | 0.700 |
| Example 1 | | |
| Comparative | Compound B | 0.200 |
| Example 2 | | |

Based on the comparing result of Present Examples 1 to 4 and Comparative Examples 1 and 2, it may be identified that the oxygen permeability of the single film manufactured with the compound according to the present disclosure is reduced.

The structures of the compounds as used in Present Examples 1 to 4 and Comparative Examples 1 and 2 are shown in Table 6 below.

TABLE 6
Compound A

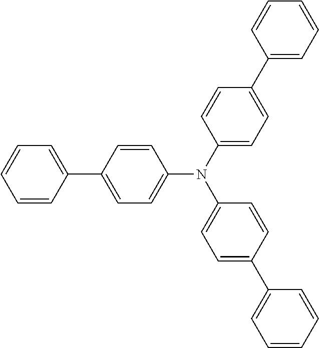 [SMILES: c1ccc(-c2ccc(N(c3ccc(-c4ccccc4)cc3)c3ccc(-c4ccccc4)cc3)cc2)cc1]

Compound B

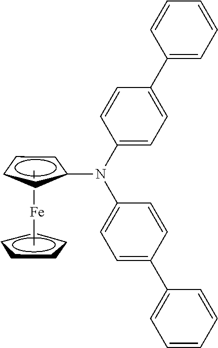

Compound 1

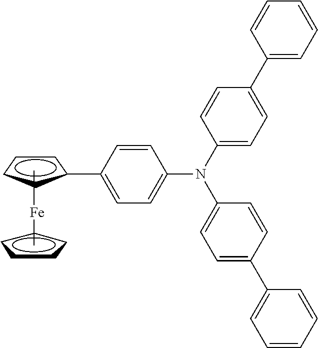

Compound 7

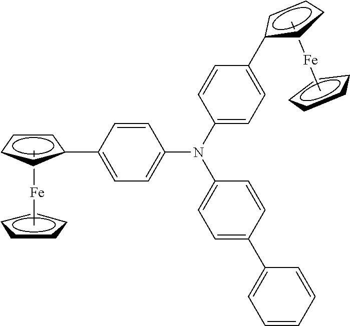

Compound 6

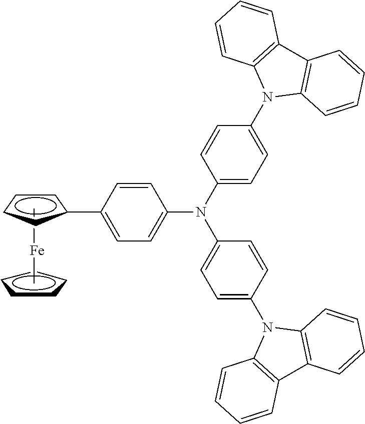

Compound 8

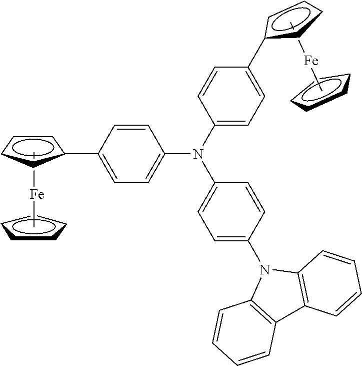

### [Experimental Example 2] Device Experiment Results

A substrate on which ITO (100 nm) as a positive electrode of an organic light-emitting device was deposited was patterned in a distinguishing manner of a positive electrode area, a negative electrode area, and an insulating layer area from each other in an exposure (Photo-Lithography) process. Then, for the purpose of increasing a work-function of the positive electrode and cleaning, a surface-treatment was performed thereon using UV-ozone and O₂:N₂ plasma.

Next, 1,4,5,8,9,11-hexaazatriphenylene-hexacarbonitrile (HAT-CN) was formed on the positive electrode to form a hole injection layer (HIL) of a thickness of 10 nm.

Then, on top of the hole injection layer, N4,N4,N4′,N4′-Tetra([1,1′-biphenyl]-4-yl)-[1,1′-biphenyl]-4,4′-diamine was vacuum deposited to form a hole transport layer of a thickness of 90 nm. N-phenyl-N-(4-(spiro[benzo[d,e]anthracene-7,9′-fluorene]-2′-yl)phenyl)dibenzo[b,d]furan-4-amine was formed on the hole transport layer (HTL) to form an electron blocking layer (EBL) of a thickness of 15 nm.

While 25 nm of 9,10-bis(2-naphthyl)anthracene (ADN) as a host was deposited on the electron blocking layer (EBL), 2,12-di-tert-butyl-5,9-bis(4-(tert-butyl)phenyl)-7-(3,5-di-tert-butylphenyl)-5,9-dihydro5,9-diaza-13b-boranaphtho[3,2,1-de]anthracene (t-DABNA-dtB) was doped into the host at about 3 wt %. Thus, the light emitting layer was formed. Thereon, a mixture of 2-(4-(9,10-di(naphthalene-2-yl)anthracene-2-yl)phenyl)-1-phenyl-1H-benzo[d]imidazole and Liq at a weight ratio of 1:1 was deposited to form an electron transport layer (ETL) of 25 nm. Then, Liq as an electron injection layer (EIL) of 1 nm was deposited on the electron transport layer, and then, aluminum was deposited thereon to form the negative electrode of a thickness of 100 nm.

A capping layer of a thickness of 60 nm was deposited on the negative electrode. Only a first capping layer was deposited, or a second capping layer with a thickness of 30 nm was additionally deposited on the first capping layer with a thickness of 30 nm. Additionally, when only the first capping layer was deposited, only a single material (hereinafter referred to as Material 1) was used or a mixed material (hereinafter referred to as Materials 1 and 2, in this case, a ratio of 1:1) was used. The compounds as shown in Table 7 below were used as the materials for the capping layer.

TABLE 7
Present Example/

| Comparative | First capping layer | | Second capping layer |
|---|---|---|---|
| Example | Material 1 | Material 2 | Material |
| Present | Compound 1 | — | — |
| Example 1 | | | |
| Present | DNTPD | Compound 1 | — |
| Example 2 | | | |
| Present | DNTPD | — | Compound 1 |
| Example3 | | | |
| Comparative | DNTPD | — | — |
| Example 1 | | | |
| Comparative | Compound B | — | — |
| Example 2 | | | |
| Comparative | Compound C | — | — |
| Example 3 | | | |
| Comparative | DNTPD | Compound B | |
| Example 4 | | | |
| Comparative | DNTPD | | Compound B |
| Example 5 | | | |

The structures of the compounds used in the Table 7 are shown in Table 8 below.

TABLE 8

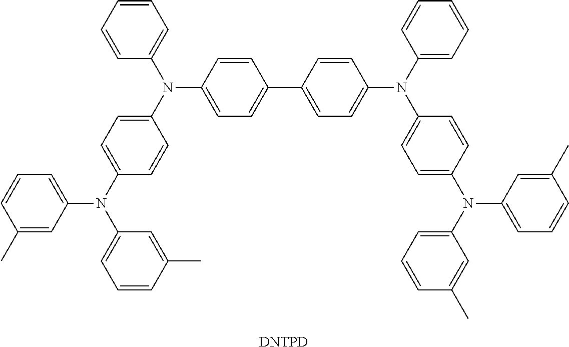

| | |
|---|---|
| 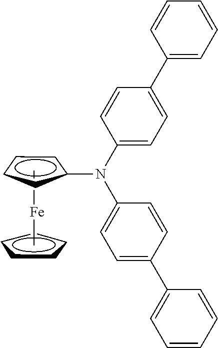 | Compound B |
| 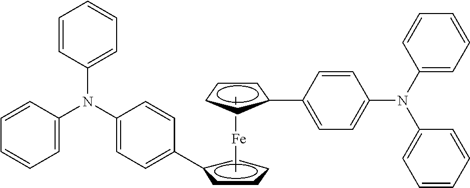 | Compound C |

Current efficiency (Cd/A) of the device was measured by applying 10 mA/cm² current to the above organic light-emitting device with CS-2000 (available from KONICA MINOLTA Co.) at the time of initial production of the device, in 6-month storage, and in 9-month storage. The lifetime (LT95) of the device was measured by identifying a time duration for which the luminance had decreased from the initial luminance to 95% thereof while operating the device at a constant current of 10 mA/cm² using M6000 (available from McScience Co.). The measurement results are shown in Table 9 below.

TABLE 9

| | At time of initial | | | | | |
|---|---|---|---|---|---|---|
| | production of device | | In 6-month storage | | In 9-month storage | |
| | Current | | Current | | Current | |
| | Efficiency | Lifetime(LT | Efficiency | Lifetime | Efficiency | Lifetime |
| | (Cd/A) | 95) | (Cd/A) | (LT95) | (Cd/A) | (LT95) |
| Present Example 1 | 16.1 | 220 | 16.2 | 222 | 15.8 | 220 |
| Present Example 2 | 20.0 | 255 | 19.8 | 235 | 19.4 | 238 |
| Present Example 3 | 18.4 | 267 | 18.5 | 265 | 17.8 | 265 |
| Comparative Example 1 | 18.1 | 210 | 10.8 | 168 | 10.5 | 153 |
| Comparative Example 2 | 15.8 | 200 | 12.4 | 160 | 10.2 | 120 |
| Comparative Example 3 | 15.5 | 190 | 12.1 | 135 | 9.4 | 94 |
| Comparative Example 4 | 18.2 | 205 | 13.3 | 148 | 10.3 | 121 |
| Comparative Example 5 | 16.4 | 200 | 12.6 | 162 | 9.8 | 122 |

Based on the Table 9, it was identified that when the compound of the present disclosure was used as the capping layer material, it blocked oxygen and moisture such that the efficiency and lifetime of the device were maintained even when the device was stored for a long period of time.

Although the embodiments of the present disclosure have been described above with reference to the accompanying drawings, the present disclosure may not be limited to the embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that the embodiments as described above are not restrictive but illustrative in all respects. Although the embodiments of the present disclosure have been described in detail above, the scope of the present disclosure is not limited thereto, and various changes, applications and modifications can be made by a skilled person in the art within the concept and scope of the present disclosure as hereinafter claimed.

What is claimed is:

1. An organic compound represented by a following Chemical Formula 1: 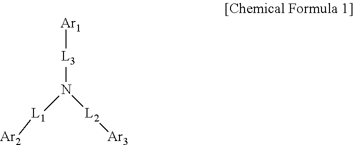
wherein L₁, L₂ and L₃ are identical with or different from each other, and each of L₁, L₂ and L₃ independently represents one selected from a group consisting of a single bond, a substituted or unsubstituted arylene group having 6 to 30 carbon atoms, a substituted or unsubstituted heteroarylene group having 1 to 30 carbon atoms, a substituted or unsubstituted alkylene group having 1 to 10 carbon atoms, a substituted or unsubstituted cycloalkylene group having 3 to 10 carbon atoms, a substituted or unsubstituted alkenylene group having 2 to 10 carbon atoms, a substituted or unsubstituted cycloalkenylene group having 3 to 10 carbon atoms, a substituted or unsubstituted heteroalkylene group having 1 to 10 carbon atoms, a substituted or unsubstituted heterocycloalkylene group having 2 to 10 carbon atoms, a substituted or unsubstituted heteroalkenylene group having 2 to 10 carbon atoms, and a substituted or unsubstituted heterocycloalkenylene group having 2 to 10 carbon atoms,
wherein Ar₁, Ar₂ and Ar₃ are identical with or different from each other, and each of Ar₁, Ar₂ and Ar₃ independently represents one selected from a group consisting of hydrogen, a substituted or unsubstituted aryl group having 6 to 30 carbon atoms, a substituted or unsubstituted heteroaryl group having 1 to 30 carbon atoms, a substituted or unsubstituted alkyl group having 1 to 20 carbon atoms, a substituted or unsubstituted cycloalkyl group having 3 to 20 carbon atoms, a substituted or unsubstituted heteroalkyl group having 1 to 20 carbon atoms, a substituted or unsubstituted heterocycloalkyl group having 2 to 20 carbon atoms, a substituted or unsubstituted aralkyl group having 6 to 30 carbon atoms, a substituted or unsubstituted alkenyl group having 2 to 20 carbon atoms, a substituted or unsubstituted cycloalkenyl group having 3 to 20 carbon atoms, a substituted or unsubstituted heteroalkenyl group having 2 to 20 carbon atoms, and an organometallic compound group represented by a following Chemical Formula 2,
wherein at least one of Ar₁, Ar₂ and Ar₃ is selected as an organometallic compound group represented by the following Chemical Formula 2: 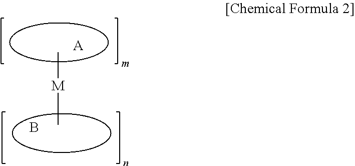
wherein the A ring and the B ring are identical with or different from each other, and each of the A ring and the B ring independently has a monocyclic or polycyclic ring structure including a 5-membered and/or 6-membered carbocyclic or heterocyclic ring,
wherein each of m and n is an integer from 1 to 8,
wherein M independently represents one selected from a group consisting of platinum (Pt), palladium (Pd), copper (Cu), iron (Fe), silver (Ag), gold (Au), rhodium (Rh), ruthenium (Ru), osmium (Os), titanium (Ti), zirconium (Zr), hafnium (Hf), europium (Eu), terbium (Tb), and thulium (Tm),
wherein when a substituent is present in each of L₁, L₂, L₃, Ar₁, Ar₂ and Ar₃, each of the substituents independently represents at least one selected from a group consisting of deuterium, a cyano group, a nitro group, a halogen group, a hydroxy group, an alkyl group having 1 to 30 carbon atoms, an alkenyl group having 2 to 30 carbon atoms, an alkynyl group having 2 to 24 carbon atoms, a heteroalkyl group having 2 to 30 carbon atoms, an aralkyl group having 6 to 30 carbon atoms, a cycloalkyl group having 3 to 20 carbon atoms, a heterocycloalkyl group having 3 to 20 carbon atoms, an aryl group having 6 to 30 carbon atoms, a heteroaryl group having 2 to 30 carbon atoms, a heteroarylalkyl group having 3 to 30 carbon atoms, an alkoxy group having 1 to 30 carbon atoms, an alkylsilyl group having 1 to 30 carbon atoms, an arylsilyl group having 6 to 30 carbon atoms, and an aryloxy group having 6 to 30 carbon atoms, wherein when a plurality of substituents is present in each of L₁, L₂, L₃, Ar₁, Ar₂ and Ar₃, the plurality of substituents are identical with or different from each other.

2. The organic compound of claim 1, wherein L₁, L₂ and L₃ are identical with or different from each other, and each of L₁, L₂ and L₃ independently represents one selected from a group consisting of a single bond, a substituted or unsubstituted arylene group having 6 to 30 carbon atoms, and a substituted or unsubstituted heteroarylene group having 5 to 30 carbon atoms.

3. The organic compound of claim 1, wherein Ar₁, Ar₂ and Ar₃ are identical with or different from each other, and each of Ar₁, Ar₂ and Ar₃ independently represents one selected from a group consisting of hydrogen, a substituted or unsubstituted aryl group having 6 to 30 carbon atoms, and a substituted or unsubstituted heteroaryl group having 5 to 30 carbon atoms.

4. The organic compound of claim 1, wherein when the substituent is present in each of Ar₁, Ar₂ and Ar₃, each of the substituents independently represents at least one selected from a group consisting of deuterium, an aralkyl group having 6 to 30 carbon atoms, an aryl group having 6 to 30 carbon atoms, a heteroaryl group having 5 to 30 carbon atoms, a heteroarylalkyl group having 3 to 30 carbon atoms, an alkoxy group having 1 to 30 carbon atoms, an alkylsilyl group having 1 to 30 carbon atoms, an arylsilyl group having 6 to 30 carbon atoms, and an aryloxy group having 6 to 30 carbon atoms.

5. The organic compound of claim 1, wherein each of at least two of Ar₁, Ar₂ and Ar₃ is independently selected as the organometallic compound group represented by the Chemical Formula 2.

6. The organic compound of claim 1, wherein each of at least one of Ar₁, Ar₂ and Ar₃ is selected as an organometallic compound group represented by a following Chemical Formula 4:

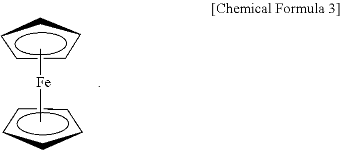

7. The organic compound of claim 1, wherein M is iron (Fe).

8. An organic light-emitting device comprising:
a first electrode;
a second electrode facing the first electrode; and
one or more of organic layer disposed between the first electrode and the second electrode,
wherein one or more of capping layer is disposed on a surface of the first electrode or the second electrode,
wherein the at least one capping layer includes the organic compound represented by chemical formula 1 according to claim 1.

9. The organic light-emitting device of claim 8, wherein the capping layer comprising the organic compound represented by chemical formula 1 according to claim 1 further includes at least one selected from a group consisting of an arylamine derivative, a naphthalene derivative, a anthracene derivative, a phenanthrene derivative, a carbazole derivative, a pyridine derivative, a dibenzofuran derivative, a dibenzothiophene derivative, a pyrimidine derivative, a quinoline derivative, a isoquinoline derivative, a benzoxazole derivative, a benzothiazole derivative, a benzoimidazole derivative, a tris(8-hydroxyquinolinato)aluminum (Alq₃), LiF, Liq, LizO, BaO, NaCl and CsF.

10. The organic light-emitting device of claim 8, wherein the at least one organic material layer includes at least one selected from a group consisting of a hole injection layer, a hole transport layer, an electron blocking layer, a light-emitting layer, a hole blocking layer, an electron transport layer, and an electron injection layer.
